(19) United States
(12) Patent Application Publication
(10) Pub. No.: US 2026/0144067 A1
(43) Pub. Date: May 21, 2026

(54) DIE STRUCTURE AND METHOD FOR FORMING SEMICONDUCTOR PACKAGE STRUCTURE

(71) Applicant: Taiwan Semiconductor Manufacturing Company, Ltd., Hsinchu (TW)

(72) Inventors: Chieh-Lung LAI, Taichung City (TW); Meng-Liang LIN, Hsinchu (TW); Hsien-Wei CHEN, Hsinchu City (TW); Kathy Wei YAN, Hsinchu (TW)

(73) Assignee: Taiwan Semiconductor Manufacturing Company, Ltd., Hsinchu (TW)

(21) Appl. No.: 18/952,247

(22) Filed: Nov. 19, 2024

(51) Int. Cl. H01L 23/00; H01L 25/00; H01L 25/10

(52) U.S. Cl. CPC H10W 42/121; H10W 90/00; H10W 70/60; H10W 72/012; H10W 72/016; H10W 72/072; H10W 72/874; H10W 90/22; H10W 90/734

(57) ABSTRACT

A die structure is provided. The die structure includes a first semiconductor die, a second semiconductor die disposed over the first semiconductor die, a first bonding layer disposed over the second semiconductor die, a high-k layer disposed over the bonding layer, and a substrate disposed over the high-k layer. The compressive film stress of the first bonding layer is less than the compressive film stress of the high-k layer.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

Many integrated circuits are typically manufactured on a semiconductor wafer. The dies of the wafer may be processed and packaged at the wafer level, and various technologies have been developed for wafer level packaging. Since the chip package structure may need to include different chips with different functions, it is a challenge to form a reliable chip package structure with different chips.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a cross-sectional view of a semiconductor die, in accordance with some embodiments.

FIG. 1B to FIG. 1I are cross-sectional views of intermediate stages in the manufacturing of a die structure, in accordance with some embodiments.

FIG. 1J is a top view showing some elements of the die structure, in accordance with some embodiments.

FIG. 1K to FIG. 1Q are cross-sectional views of intermediate stages in the manufacturing of a semiconductor package structure, in accordance with some embodiments.

FIG. 2 is a cross-sectional view of a die structure, in accordance with some embodiments of the present disclosure.

FIG. 3A is a cross-sectional view of a die structure, in accordance with some embodiments of the present disclosure.

FIG. 3B is a top view of the die structure, in accordance with some embodiments of the present disclosure.

FIG. 3C to FIG. 3F are cross-sectional views of intermediate stages in the manufacturing of a die structure, in accordance with some embodiments.

FIG. 4A is a cross-sectional view of a die structure, in accordance with some embodiments of the present disclosure.

FIG. 4B is a top view of the die structure, in accordance with some embodiments of the present disclosure.

FIG. 4C is a cross-sectional view of a die structure, in accordance with some embodiments of the present disclosure.

FIG. 4D is a top view of the die structure, in accordance with some embodiments of the present disclosure.

FIG. 4E is a cross-sectional view of a die structure, in accordance with some embodiments of the present disclosure.

FIG. 4F is a top view of the die structure, in accordance with some embodiments of the present disclosure.

FIG. 4G is a cross-sectional view of a die structure, in accordance with some embodiments of the present disclosure.

FIG. 4H is a top view of the die structure, in accordance with some embodiments of the present disclosure.

FIG. 4I is a cross-sectional view of a die structure, in accordance with some embodiments of the present disclosure.

FIG. 4J is a top view of the die structure, in accordance with some embodiments of the present disclosure.

FIG. 5A is a cross-sectional view of a die structure, in accordance with some embodiments of the present disclosure

FIG. 5B is a top view of the die structure, in accordance with some embodiments of the present disclosure.

FIG. 5C is a cross-sectional view of a die structure, in accordance with some embodiments of the present disclosure.

FIG. 5D is a top view of the die structure, in accordance with some embodiments of the present disclosure.

FIG. 6A is a cross-sectional view of a die structure, in accordance with some embodiments of the present disclosure.

FIG. 6B is a cross-sectional view of a die structure, in accordance with some embodiments of the present disclosure.

FIG. 6C is a cross-sectional view of a die structure, in accordance with some embodiments of the present disclosure.

FIG. 7A to FIG. 7I are cross-sectional views of intermediate stages in the manufacturing of a semiconductor package structure, in accordance with some embodiments.

FIG. 7J is a top view of the die structure, in accordance with some embodiments.

FIG. 7K to FIG. 7Q are cross-sectional views of intermediate stages in the manufacturing of a semiconductor package structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, the present disclosure may repeat reference numerals and/or letters in the various examples. This repetition is for the purpose of simplicity and clarity and does not in itself dictate a relationship between the various embodiments and/or configurations discussed.

The terms “about” and “substantially” typically mean +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. When there is no specific description, the stated value includes the meaning of “about” or “substantially”.

Furthermore, the phrase “in a range between a first value and a second value” or “in a range from a first value to a second value” indicates that the range includes the first value, the second value, and other values between them.

Use of ordinal terms such as “first”, “second”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

Embodiments of the present disclosure relates to die structures designed to control warpage, particularly in systems on integrated chips (SoIC). These structures include a bonding structure between the substrate and the dies. The bonding structure provides compressive film stress to counteract warping caused by temperature variation during the process.

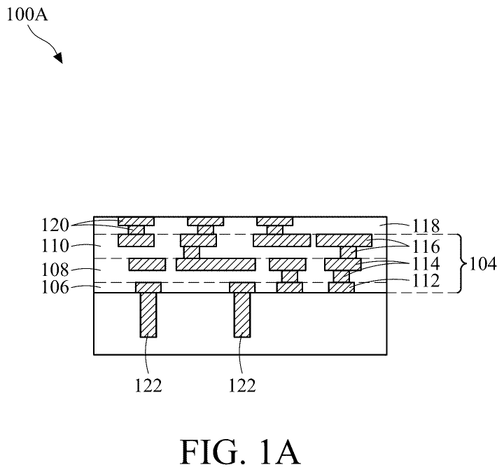

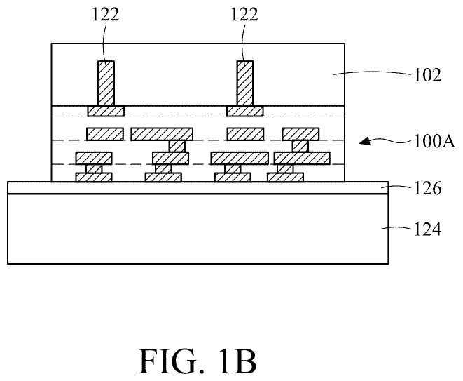

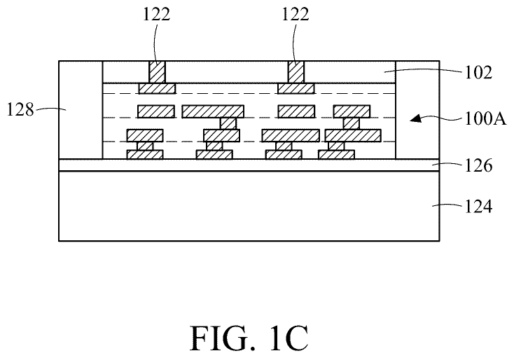

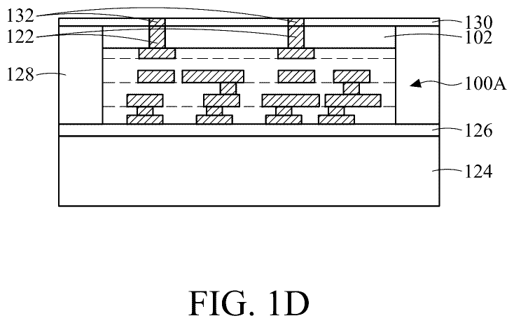

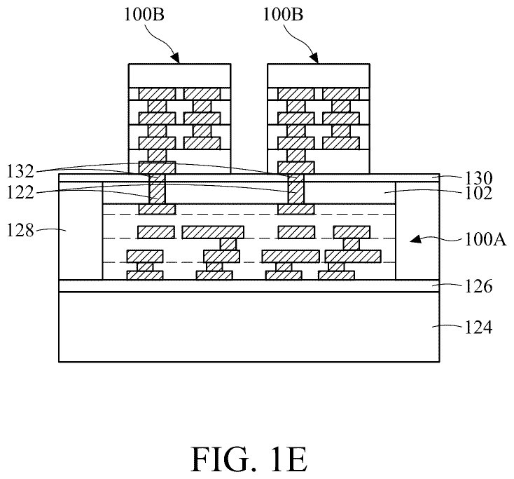

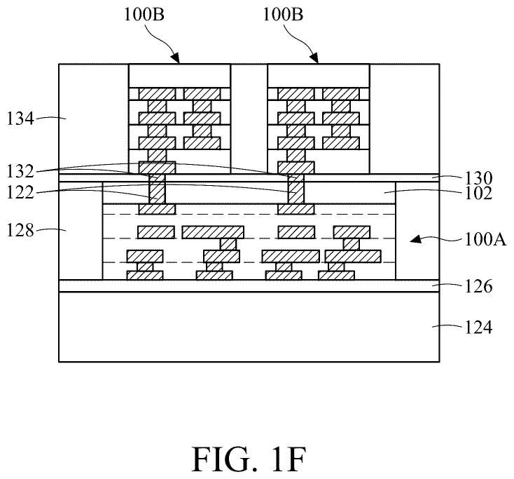

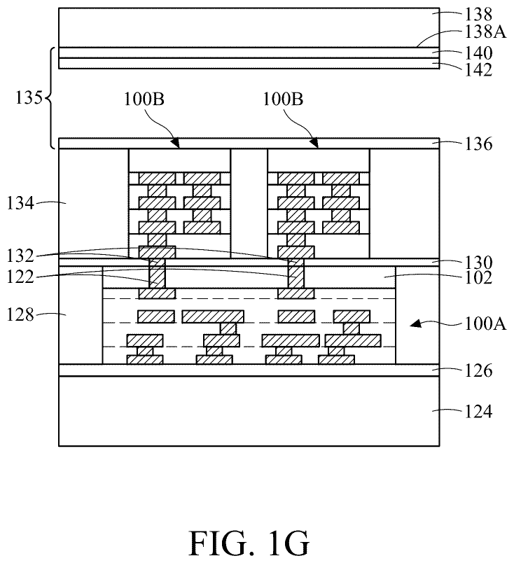

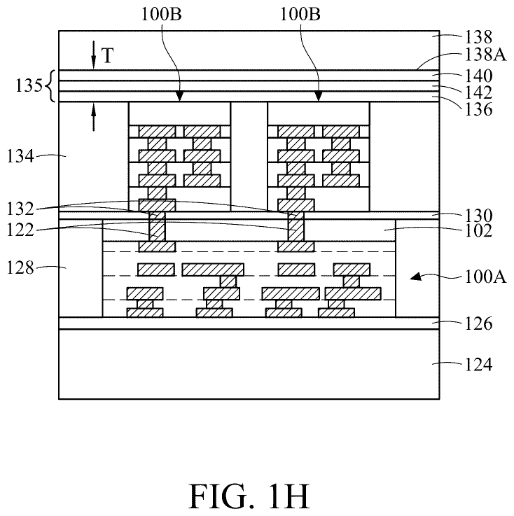

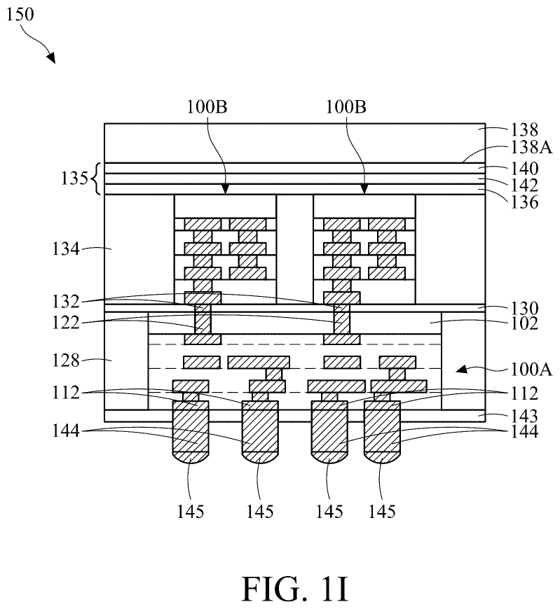

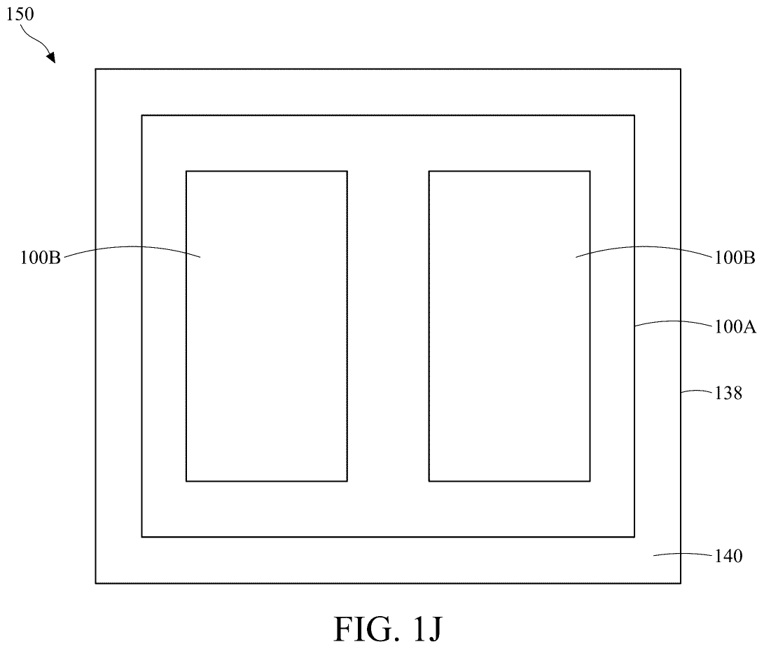

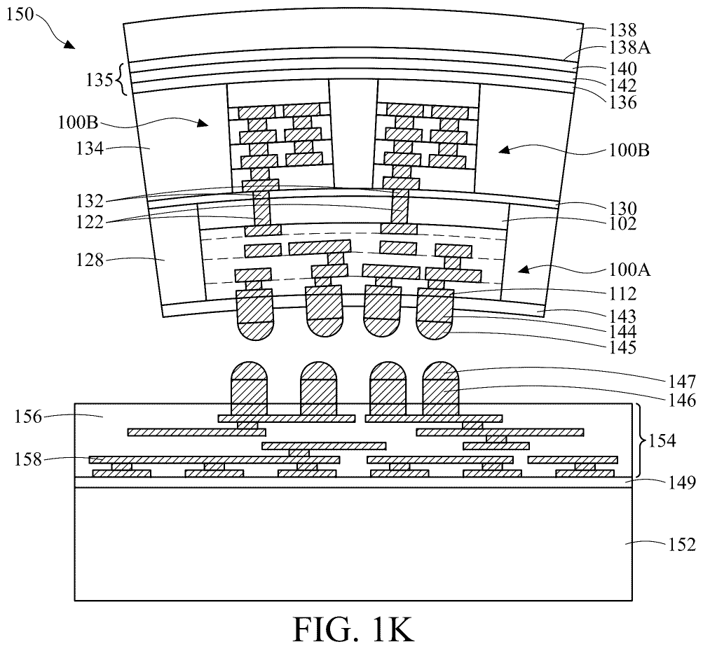

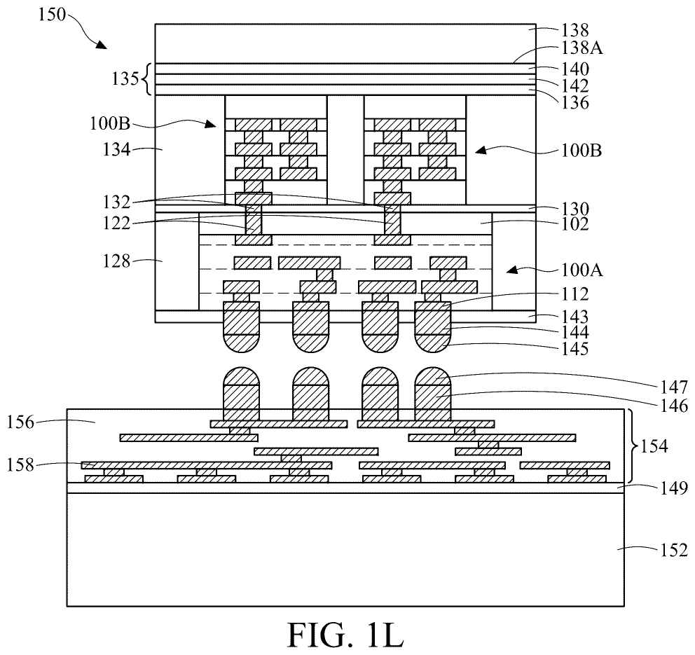

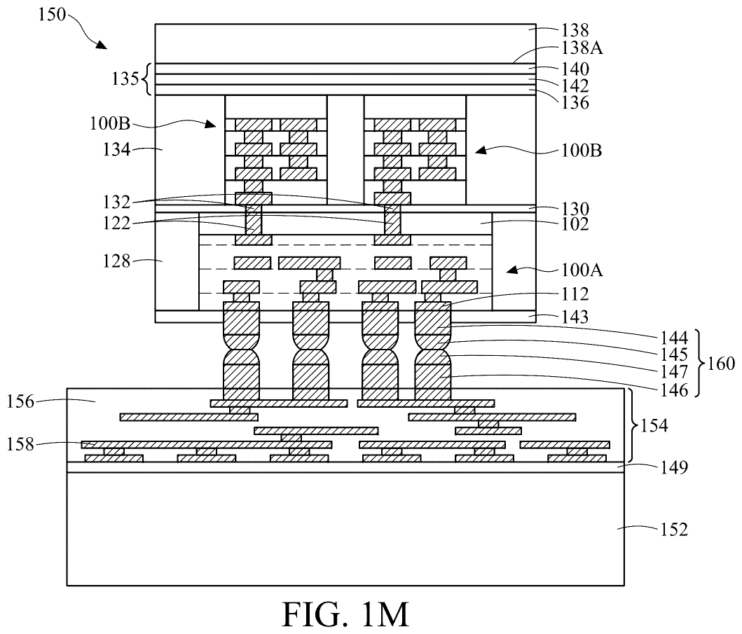

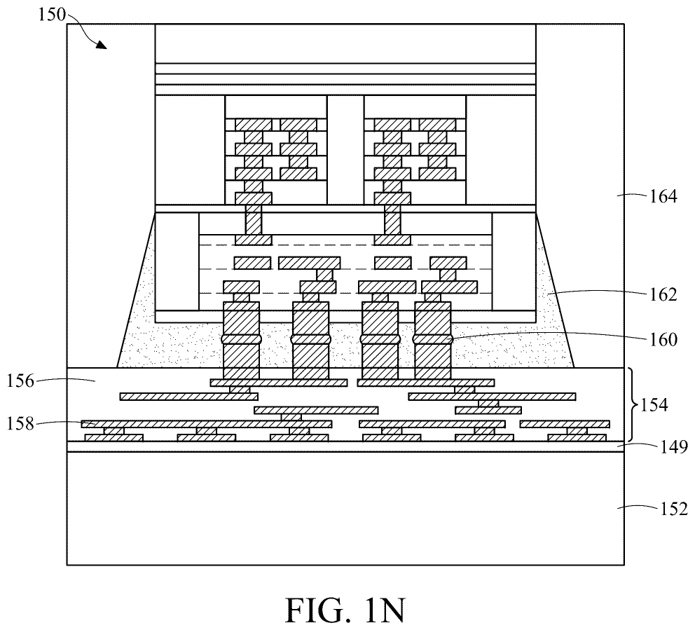

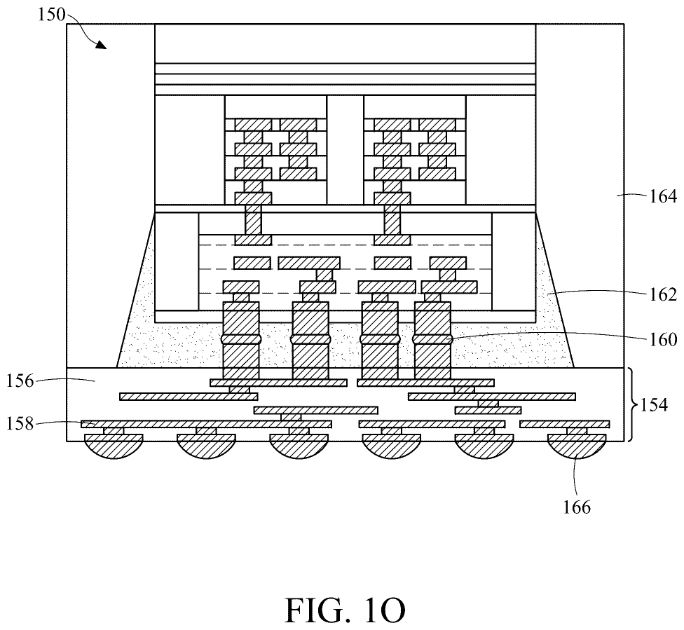

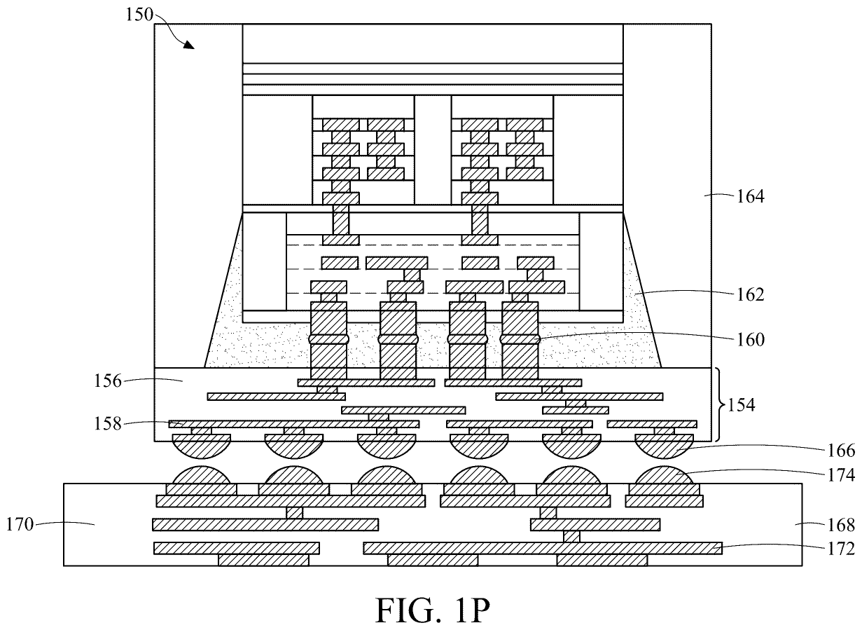

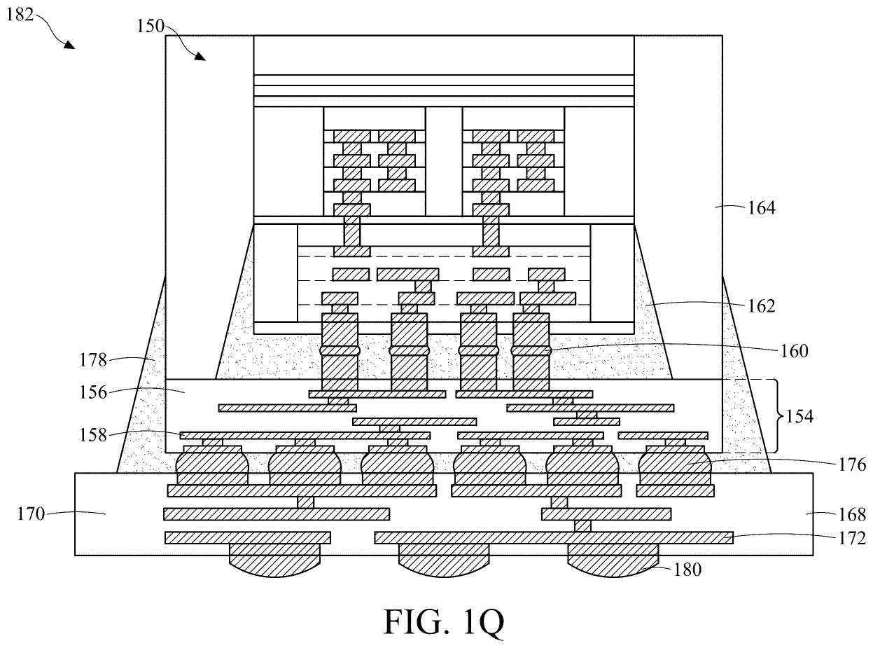

FIG. 1A is a cross-sectional view of a semiconductor die 100A, in accordance with some embodiments. The semiconductor die 100A will be bonded to other dies in subsequent processing to form a die structure. In some embodiments, the semiconductor die 100A may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof.

The semiconductor die 100A may be formed in a wafer, which may include different device regions that are singulated in subsequent steps to form a plurality of integrated circuit dies. The semiconductor die 100A may be processed according to applicable manufacturing processes to form integrated circuits. For example, the semiconductor die 100A includes a substrate 102, such as silicon, doped or undoped, or an active layer of a semiconductor-on-insulator (SOI) substrate. The substrate 102 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The substrate 102 has an active surface (e.g., the surface facing upwards in FIG. 1A), sometimes called a front-side, and an inactive surface (e.g., the surface facing downwards in FIG. 1A), sometimes called a back-side.

In some embodiments, devices (not separately illustrated) are disposed at the active surface of the substrate 102. The devices may be active devices (e.g., transistors, diodes, etc.), passive devices (e.g., capacitors, resistors, etc.), other suitable elements, or a combination thereof. An interconnect structure 104 is disposed over the active surface of the substrate 102. The interconnect structure 104 interconnects the devices of the substrate 102 to form an integrated circuit. The interconnect structure 104 may be formed of, for example, conductive features 112, 114, and 116 disposed in dielectric layers 106, 108, and 110, respectively.

In some embodiments, the dielectric layers 106, 108, and 110 may include silicon oxide or a suitable low-k material, such as porous silicon oxide, organosilicate glass, hydrogen silsesquioxane (HSQ), methyl silsesquioxane (MSQ), polysilsesquioxane, or a combination thereof. The conductive features 112, 114, and 116 may include horizontal wiring features and conductive vias, which may be formed in the dielectric layers 106, 108, and 110 by a damascene process, such as a single damascene process, a dual damascene process, or the like. In a single damascene process, a trench or a via opening is formed in one of the dielectric layers 106, 108, and 110, and the trench or the via opening is filled with a conductive material.

In some embodiments, the conductive features 112, 114, and 116 may be formed of a suitable conductive material, such as copper, tungsten, aluminum, silver, gold, a combination thereof, or the like, which can be formed by, for example, plating or the like. In some embodiments, the conductive features 112, 114, and 116 may include a liner layer (not shown), such as a diffusion barrier layer, an adhesion layer, a metal seed layer, a combination thereof, or the like. The liner layer may include TaN, Ta, Ti, TiN, Cu, a combination thereof, or the like. The conductive features 112, 114, and 116 may also include a low-resistance conductive material disposed over the liner layer. For example, the low-resistance conductive material may include Cu, Al, Co, Ag, Au, W, a combination thereof, or the like. The conductive features 112, 114, and 116 are electrically coupled to the devices of the substrate 102.

Optionally, conductive vias 122 extend into the interconnect structure 104 and/or the substrate 102. The conductive vias 122 are electrically coupled to the conductive features 112, 114, and 116 of the interconnect structure 104. As an example to form the conductive vias 122, recesses can be formed in the interconnect structure 104 and/or the substrate 102 by, for example, etching, milling, laser techniques, a combination thereof, or the like. In some embodiments, a thin barrier layer may be conformally deposited in the recesses, such as by chemical vapor deposition (CVD), atomic layer deposition (ALD), physical vapor deposition (PVD), thermal oxidation, a combination thereof, or the like. The barrier layer may be formed from an oxide, a nitride, combinations thereof, or the like. A conductive material may be deposited over the barrier layer and in the recesses. The conductive material may be formed by an electro-chemical plating process, CVD, ALD, PVD, a combination thereof, or the like. Examples of conductive materials include copper, tungsten, aluminum, silver, gold, a combination thereof, or the like. Excess conductive material and barrier layer is removed from a surface of the interconnect structure 104 or the substrate 102 by, for example, a chemical-mechanical polish (CMP). The remaining portions of the barrier layer and conductive material in the recesses form the conductive vias 122. After their initial formation, the conductive vias 122 may be buried in the substrate 102. The substrate 102 may be thinned in subsequent processing to expose the conductive vias 122 at the inactive surface of the substrate 102. After the exposure process, the conductive vias 122 are through-substrate vias (TSVs), such as through-silicon vias, that extend through the substrate 102.

A dielectric layer 118 is over the interconnect structure 104, at the front-side of the semiconductor die 100A. The dielectric layer 118 may be formed of an oxide such as silicon oxide, phosphosilicate glass (PSG), borosilicate glass (BSG), boron-doped phosphosilicate glass (BPSG), a tetraethyl orthosilicate (TEOS) based oxide, or the like; a nitride such as silicon nitride or the like; a polymer such as polybenzoxazole (PBO), polyimide, a benzocyclobutene (BCB) based polymer, or the like; a combination thereof; or the like. The dielectric layer 118 may be formed, for example, by CVD, spin coating, lamination, or the like. In some embodiments, the dielectric layer 118 is formed of TEOS-based silicon oxide. Optionally, one or more passivation layer(s) (not separately illustrated) are disposed between the dielectric layer 118 and the interconnect structure 104.

Conductive features 120 extend through the dielectric layer 118 and connected to the conductive feature 116. The conductive features 120 may include conductive pillars, pads, vias, or the like, to which external connections can be made. In some embodiments, the conductive features 120 include bond pads at the front-side of the semiconductor die 100A, and include bond pad vias that connect the bond pads to the conductive feature 116 of the interconnect structure 104. In such embodiments, the conductive features 120 (including the bond pads and the bond pad vias) may be formed by a damascene process, such as a single damascene process, a dual damascene process, or the like. The conductive features 120 may be formed of a suitable conductive material, such as copper, tungsten, aluminum, silver, gold, a combination thereof, or the like, which can be formed by, for example, plating or the like. In some embodiments, a planarization process such as a chemical mechanical polish (CMP), an etch-back process, combinations thereof, or the like is utilized.

In some embodiments, the semiconductor die 100A is a stacked device that includes multiple substrates 102. For example, the semiconductor die 100A may be a memory device that includes multiple memory dies such as a hybrid memory cube (HMC) device, a high bandwidth memory (HBM) device, or the like. In such embodiments, the semiconductor die 100A includes multiple substrates 102 interconnected by TSVs. Each of the substrates 102 may (or may not) have a separate interconnect structure 104.

FIG. 1B to FIG. 1I are cross-sectional views of intermediate stages in the manufacturing of a die structure 150, in accordance with some embodiments. As shown in FIG. 1B, a carrier substrate 124 is provided. The carrier substrate 124 may be a glass carrier substrate, a ceramic carrier substrate, a wafer (e.g., a silicon wafer), or the like. The carrier substrate 124 may provide structural support during subsequent processing steps and in the completed device.

In some embodiments, the semiconductor die 100A is attached to the carrier substrate 124 in a face-down manner, such that the front-side of the semiconductor die 100A is attached to the carrier substrate 124. In some embodiments, the semiconductor die 100A may be attached to the carrier substrate 124 by placing the semiconductor die 100A on the carrier substrate 124, and then bonding the semiconductor die 100A to the carrier substrate 124. The semiconductor die 100A may be placed by, e.g., a pick-and-place process. The bonding process may include fusion bonding, dielectric bonding, or the like.

As an example of the bonding process, the semiconductor die 100A may be bonded to the carrier substrate 124 with one or more bonding layer 126. The bonding layer 126 are on front-sides of the semiconductor die 100A and/or on a surface of the carrier substrate 124. In some embodiments, the bonding layer 126 include a release layer, such as an epoxy-based thermal-release material, which loses its adhesive property when heated, such as a light-to-heat-conversion (LTHC) release coating; an ultra-violet (UV) glue, which loses its adhesive property when exposed to UV light; or the like. In some embodiments, the bonding layer 126 include an adhesive, such as a suitable epoxy, a die attach film (DAF), or the like. In some embodiments, the bonding layer 126 include an oxide layer such as a layer of silicon oxide. The bonding layer 126 may be applied to front-sides of the semiconductor die 100A, may be applied over the surface of the carrier substrate 124, and/or the like. For example, the bonding layer 126 may be applied to the front-sides of the semiconductor die 100A before singulating to separate the semiconductor die 100A.

In FIG. 1C, a dielectric material 128 is formed around the semiconductor die 100A. Initially, the dielectric material 128 may be formed on the semiconductor die 100A, such that the dielectric material 128 buries or covers the semiconductor die 100A. Afterwards, a planarization process such as a chemical mechanical polish (CMP), an etch-back process, combinations thereof, or the like may be performed to remove excess dielectric material 128 and a portion of the substrate 102 to expose the conductive vias 122. In some embodiments, the dielectric material 128 may be formed of one or more dielectric materials, which include oxides such as silicon oxide, phosphosilicate glass (PSG), borosilicate glass (BSG), boron-doped phosphosilicate glass (BPSG), a tetraethyl orthosilicate (TEOS) based oxide, or the like; nitrides such as silicon nitride or the like; combinations thereof; or the like, which may be formed by a suitable deposition process such as chemical vapor deposition (CVD), atomic layer deposition (ALD), or the like.

In FIG. 1D, a dielectric layer 130 is formed on the top surfaces of the dielectric material 128 and the semiconductor die 100A. The dielectric layer 130 may be formed of a dielectric material, such as silicon oxide, phosphosilicate glass (PSG), borosilicate glass (BSG), boron-doped phosphosilicate glass (BPSG), or the like, which may be formed by CVD, ALD, or the like. The dielectric layer 130 may be formed of a low-k dielectric material whose k-value (dielectric constant) is smaller than that of silicon oxide, which is about 3.9. In some embodiments, the low-k dielectric material includes a porous organosilicate thin film such as SiOCH, tetraethylorthosilicate (TEOS) oxide, undoped silicate glass, doped silicon oxide such as borophosphosilicate glass (BPSG), fused silica glass (FSG), phosphosilicate glass (PSG), fluorine-doped silicon dioxide, carbon-doped silicon dioxide, porous silicon dioxide, porous carbon-doped silicon dioxide, silicon carbon nitride (SiCN), silicon oxycarbide (SiOCN), spin-on silicon based polymeric dielectrics, or combinations thereof.

In some embodiments, bond pads 132 are formed in the dielectric layer 130. The bond pads 132 extend through the dielectric layer 130 to contact the conductive vias 122. In some embodiments, the bond pads 132 may be formed by a damascene process, such as a single damascene process. As an example to form the bond pads 132, the dielectric layer 130 is patterned utilizing photolithography and etching techniques to form openings corresponding to the desired pattern of the bond pads 132. The openings may then be filled with a conductive material. Suitable conductive materials include copper, silver, gold, tungsten, aluminum, combinations thereof, or the like, which may be formed by electroplating or the like. A removal process may be performed to remove excess conductive material from a surface of the dielectric layer 130. In some embodiments, a planarization process such as a chemical mechanical polish (CMP), an etch-back process, combinations thereof, or the like is utilized. The remaining conductive material forms the bond pads 132 in the openings.

In FIG. 1E, semiconductor dies 100B are attached to the dielectric layer 130 and the bond pads 132, such that the front-sides of the semiconductor dies 100B face the back-sides of the semiconductor die 100A. In some embodiments, the semiconductor dies 100B may be memory dies, power management dies, or the like. The function of the semiconductor dies 100B may (or may not) be different than the function of the semiconductor die 100A. The semiconductor die 100A and the semiconductor dies 100B may be formed in processes of the same technology node, or may be formed in processes of different technology nodes. For example, the semiconductor die 100A may be of a more advanced process node than the semiconductor dies 100B. The semiconductor die 100A may be wider than the semiconductor dies 100B.

The semiconductor dies 100B may be attached to the dielectric layer 130 and the bond pads 132 by placing the semiconductor dies 100B on the dielectric layer 130 and the bond pads 132, and then bonding the semiconductor dies 100B to the dielectric layer 130 and the bond pads 132. The semiconductor dies 100B may be placed by, e.g., a pick-and-place process. The bonding process may include fusion bonding, dielectric bonding, metal bonding, a combination thereof (e.g., a combination of dielectric-to-dielectric bonding and metal-to-metal bonding), or the like. As an example of the bonding process, the semiconductor dies 100B may be directly bonded to the dielectric layer 130 and the bond pads 132 by a combination of dielectric-to-dielectric bonding and metal-to-metal bonding.

In FIG. 1F, a dielectric material 134 is formed around the semiconductor dies 100B. The dielectric material 134 may be formed of one or more dielectric materials. Acceptable gap-fill dielectric materials include oxides such as silicon oxide, phosphosilicate glass (PSG), borosilicate glass (BSG), boron-doped phosphosilicate glass (BPSG), a tetraethyl orthosilicate (TEOS) based oxide, or the like; nitrides such as silicon nitride or the like; combinations thereof; or the like, which may be formed by a suitable deposition process such as chemical vapor deposition (CVD), atomic layer deposition (ALD), or the like.

In some embodiments, the dielectric material 134 may initially be formed on the semiconductor dies 100B, such that the dielectric material 134 buries or covers the semiconductor dies 100B. Accordingly, the top surface of the dielectric material 134 may initially be above the back-sides of the semiconductor dies 100B. Subsequently, surfaces of the dielectric material 134 may be leveled with the back-sides of the semiconductor dies 100B to expose the semiconductor dies 100B. In some embodiments, a planarization process such as a chemical mechanical polish (CMP), an etch-back process, combinations thereof, or the like is utilized.

In FIG. 1G, a substrate 138 is provided. In some embodiments, the substrate 138 may be a glass support substrate, a ceramic support substrate, a semiconductor substrate (e.g., a silicon substrate), a wafer (e.g., a silicon wafer), or the like. The substrate 138 may provide structural support during subsequent processing steps and in the completed device. The substrate 138 may be substantially free of any active or passive devices.

In some embodiments, the substrate 138 may be attached to the dielectric material 134 and the semiconductor dies 100B with a bonding structure 135. In some embodiments, the bonding structure 135 includes a bonding layer 136 disposed over the dielectric material 134 and the semiconductor dies 100B, a warpage tuning layer 140 disposed over the bottom surface 138A of the substrate 138, and a bonding layer 142 disposed over the warpage tuning layer 140. In some embodiments, the bonding layers 136 and 142 include an oxide layer such as silicon oxide.

The causes of film stress can be visualized by imagining what occurs when too many atoms are packed into the film. The bond lengths become shorter than usual, leading the film to attempt to return to its normal bond length. This results in an outward push to create a convex curvature on the wafer, which is called as “compressive film stress”. The film stress can be defined by the following equation:

$$σ = \frac{Δ}{{r}^{2}} \cdot \frac{{( {t}_{substrate} )}^{2}}{{t}_{film}} \cdot \frac{E}{3 ( 1 - v )}$$

wherein σ represents film stress, A represents change in wafer bow, r represents radius of scan, t_{substrate} represents thickness of the substrate, t_{film} represents thickness of the film, E represents Young's modulus, and v represents Poission's ratio. In some embodiments, the warpage tuning layer 140 may be a layer having higher compressive film stress than the bonding layers 136 or 142. In some embodiments, the compressive film stress of the warpage tuning layer 140 may be greater than 100 MPa. In some embodiments, as the refractive index increases, the compressive film stress decreases accordingly. In some embodiments, the warpage tuning layer 140 may have a different refractive index than the bonding layers 136 or 142, such as the refractive index of the warpage tuning layer 140 may be lower than the refractive index of the bonding layers 136 or 142 to achieve a lower compressive film stress.

In some embodiments, the warpage tuning layer 140 may include high-k materials. For example, the warpage tuning layer 140 may include insulating materials such as SiOₓ, SiNₓ, SiOₓN_{y}, SiC; semiconductor materials such as SiGe; and conductive materials such as tungsten (W). Therefore, the warpage tuning layer 140 may also be referred to as a high-k layer 140 throughout the description.

In FIG. 1H, the substrate 138 is attached to the semiconductor dies 100B and the dielectric material 134 through the bonding structure 135. In some embodiments, a hot pressing process is applied to attach the substrate 138 to the semiconductor dies 100B and the dielectric material 134. In some embodiments, the temperature during the hot pressing process may be performed between about 100° C. and about 400° C. It should be noted that the substrate 138 (such as the bottom surface 138A) has a first curvature during the hot pressing process. In some embodiments, the bottom surface 138A of the substrate 138 is substantially flat during the hot pressing process. In some embodiments, a thickness T of the bonding structure 135 is between about 10 nm and about 10 μm.

In FIG. 1I, a de-bonding process is performed to detach (or “de-bond”) the carrier substrate 124 from the semiconductor die 100A. The dielectric material 128 and the front-sides of the semiconductor die 100A are thus exposed. In some embodiments where the bonding layer 126 include an oxide layer, the de-bonding includes applying a removal process (such as a grinding process) to the carrier substrate 124 and the bonding layer 126. In some embodiments where the bonding layer 126 include a release layer, the de-bonding includes projecting a light such as a laser light or a UV light on the bonding layer 126 so that the bonding layer 126 decomposes under the heat of the light and the carrier substrate 124 can be removed. The structure is then flipped over and placed on a tape (not separately illustrated).

Afterwards, a singulation process is performed along scribe line regions (not illustrated) to form a singulated die structure 150. The singulation process may include performing a sawing process, a laser cutting process, or the like. The die structure 150 is a component that may be subsequently implemented in a semiconductor package structure.

The die structure 150 may include additional features for attaching the die structure 150 to an additional component. In this embodiment, the die structure 150 further includes one or more passivation layer 143, conductive structures 144, and conductive structures 145. The conductive structures 145 may be used to connect the die structure 150 (e.g., the conductive structures 144) to the additional component. The passivation layer 143, the conductive structures 144, and the conductive structures 145 may be formed before or after the die structure 150 is singulated.

The passivation layer 143 may be formed on the front-sides of the semiconductor die 100A and the dielectric material 128 that were exposed by removal of the carrier substrate 124. The passivation layer 143 may be formed of one or more suitable dielectric materials such as silicon oxynitride, silicon nitride, low-k dielectrics such as carbon doped oxides, extremely low-k dielectrics such as porous carbon doped silicon oxide, or the like; a polymer such as polyimide, solder resist, polybenzoxazole (PBO), a benzocyclobutene (BCB) based polymer, molding compound, or the like; a combination thereof; or the like. In some embodiments, the passivation layer 143 may be formed by chemical vapor deposition (CVD), spin coating, lamination, the like, or a combination thereof.

The conductive structures 144 may be formed through the passivation layer 143 to contact the conductive feature 112 of the semiconductor die 100A. The conductive structures 144 may include conductive pillars, pads, or the like, to which external connections can be made. The conductive structures 144 can be formed of a conductive material, such as a metal, such as copper, aluminum, or the like, which can be formed by, for example, plating, or the like. As an example to form the conductive structures 144, the passivation layer 143 is patterned utilizing photolithography and etching techniques to form openings corresponding to the desired pattern of the conductive structures 144. The openings may then be filled with a conductive material (previously described) to form the conductive structures 144 in the openings.

The conductive structures 145 may be formed on the conductive structures 144. The conductive structures 145 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive structures 145 may include a conductive material such as solder, copper, aluminum, gold, nickel, silver, palladium, tin, the like, or a combination thereof. In some embodiments, the conductive structures 145 are formed by initially forming a layer of a reflowable material (e.g., solder) through evaporation, electroplating, printing, solder transfer, ball placement, or the like. Once a layer of solder has been formed on the structure, a reflow may be performed in order to shape the material into the desired bump shapes.

FIG. 1J is a top view showing some elements of the die structure 150, in accordance with some embodiments. As shown in FIG. 1I and FIG. 1J, the warpage tuning layer 140 overlaps the semiconductor dies 100A and 100B, and the bottom surface 138A of the substrate 138 is covered by the warpage tuning layer 140. Side surfaces of the substrate 138 and the warpage tuning layer 140 are aligned with each other.

FIG. 1K to FIG. 1Q are cross-sectional views of intermediate stages in the manufacturing of a semiconductor package structure 182, in accordance with some embodiments. In some embodiments, as shown in FIG. 1K, the temperature is reduced to room temperature (such as about 25° C.) to preform subsequent processes. In some embodiments, a carrier substrate 152 with a release film 149, and a redistribution layer (RDL) 154 is provided, and the die structure 150 may be placed over the redistribution layer 154 by, e.g., a pick-and-place process.

In some embodiments, the carrier substrate 152 may be a glass carrier, a silicon wafer, an organic carrier, or the like. The release film 149 may be formed of a polymer-based material and/or an epoxy-based thermal-release material (such as a Light-To-Heat-Conversion (LTHC) material), which is capable of being decomposed under radiation such as a laser beam, so that carrier substrate 152 may be de-bonded from the overlying structures that will be formed in subsequent processes. In accordance with some embodiments of the present disclosure, the release film 149 is applied on the carrier substrate 152 through coating.

In some embodiments, the redistribution layer 154 is provided over the release film 149. The redistribution layer 154 includes a plurality of dielectric layers 156 and a plurality of conductive feature 158 formed in the dielectric layers 156. In accordance with some embodiments, the redistribution layer 154 is pre-formed and placed on the release film 149. In some embodiments, the redistribution layer 154 may be an organic interposer comprising organic dielectric layers and redistribution lines. Alternatively, redistribution layer 154 may include a semiconductor substrate, through-vias in the semiconductor substrate, and metal lines and vias on the opposite sides of, and electrically interconnected through, the through-vias.

In accordance with alternative embodiments, the redistribution layer 154 is formed layer-by-layer starting from release film 149. In the formation of redistribution layer 154, a dielectric layer 156 is first formed on release film 149, and is then patterned to form openings. In accordance with some embodiments of the present disclosure, dielectric layer is formed of or comprises an organic material, which may be a polymer. The organic material may also be a photo-sensitive material. For example, the dielectric layer 156 may be formed of or comprises polyimide, polybenzoxazole (PBO), benzocyclobutene (BCB), or the like.

Afterwards, the conductive feature 158 are formed on the dielectric layer 156. In accordance with some embodiments, the formation of conductive feature 158 may include forming a metal seed layer (not shown), which includes some portions over dielectric layer 156, and some other portions extending into dielectric layer 156. A patterned mask (not shown) such as a photoresist is then formed over the metal seed layer, followed by a metal plating process to deposit a metallic material on the exposed metal seed layer. The patterned mask and the portions of the metal seed layer covered by the patterned mask are then removed. The process is then performed for multiple times to form the multilayered redistribution layer 154. The plated material may include copper, aluminum, cobalt, nickel, gold, silver, tungsten, or alloys thereof. In accordance with some embodiments of the present disclosure, the metal seed layer includes a titanium layer and a copper layer over the titanium layer. In some embodiments, the metal seed layer may be formed using, for example, Physical Vapor Deposition (PVD) or a like process. The plating may be performed using, for example, an electrochemical plating process.

After the formation of the dielectric layer 156, conductive structures 146 and 147 may be formed over the dielectric layer 156. The material and the process of the conductive structures 146 and 147 may be similar or identical to that of the conductive structures 144 and 145, respectively.

As shown in FIG. 1K, since the warpage tuning layer 140 provides compressive film stress, the die structure 150 will be bent by the warpage tuning layer 140 during the pick-and-place process to have a curved structure when the temperature is reduced to room temperature. For example, the substrate 138 (such as the bottom surface 138A) may have a second curvature in FIG. 1K, which is different from the first curvature during the hot pressing process shown in FIG. 1I in some embodiments. In some embodiments, the second curvature of the substrate 138 in FIG. 1K is greater than the first curvature of the substrate 138 in FIG. 1I, which means the substrate 138 becomes more planar at a higher temperature than at a lower temperature (e.g. room temperature).

In FIG. 1L, the temperature is raised for performing a bonding process, and the curvature of the substrate 138 is changed to a third curvature different from the second curvature in FIG. 1K. For example, the substrate 138 is substantially flat in FIG. 1L, which means the third curvature of the substrate 138 (such as the bottom surface 138A) in FIG. 1L is less than the second curvature of the substrate 138 in FIG. 1K. In some embodiments, the temperature is raised from room temperature to a high temperature between about 100° C. and about 400° C.

In FIG. 1M, after the temperature is raised, the conductive structures 145 may be bonded to the conductive structures 147 through solder bonding in accordance with some embodiments. Therefore, the die structure 150 is bonded to the redistribution layer 154. In some embodiments, the conductive structures 144, 145, 146, and 147 may be collectively referred to conductive structures 160. Since the substrate 138 is substantially flat, it ensures that all conductive structures 145 being in contact with the conductive structures 147 to prevent any gaps from forming between the conductive structures 145 and 147. As a result, reliability and yield can be increased based on such structure.

In FIG. 1N, underfill material 162 is dispensed into the gaps between the die structure 150 and the redistribution layer 154 and surrounding the conductive structures 160 to protect the conductive structures 160. In accordance with some embodiments, the underfill material 162 includes a base material and filler particles mixed in the base material. The base material may be a resin, an epoxy, and/or a polymer. Some example base materials include epoxy-amine, epoxy anhydride, epoxy phenol, or the like, or combinations thereof. The filler particles may be formed of a dielectric material, and may include silica, alumina, boron nitride, or the like. The filler particles may have spherical shapes. The underfill material 162 is dispensed in a flowable form, and is then cured.

Next, the die structure 150 is encapsulated in a molding layer 164. For example, the molding layer 164 may be a molding compound, a molding underfill, an epoxy, and/or a resin. The molding layer 164 may include a base material and a filler in the base material. The base material may include a polymer material, which may be or may include a plastic, an epoxy resin (such as Epoxy Cresol Novolac (ECN), biphenyl epoxy resin, or a multifunctional liquid epoxy resin), polyimide, polyethylene terephthalate (PET), polyvinyl chloride (PVC), polymethylmethacrylate (PMMA), or the like. The filler may include titanium dioxide, carbon black, calcium carbonate, silica, fiber, clay, ceramic, inorganic particles, and or the like, and may be in the form of filler particles.

In some embodiments, a planarization process such as a Chemical Mechanical Polish (CMP) process or a mechanical grinding process is then performed to polish the molding layer 164. The die structure 150 may be exposed as a result of the planarization process.

In FIG. 1O, the redistribution layer 154 is then de-bonded from the carrier substrate 152, for example, by projecting UV light or a laser beam, which penetrates through the carrier substrate 152, on the release film 149. The release film 149 decomposes under the heat of the UV light or the laser beam. The redistribution layer 154 may then be de-bonded from the carrier substrate 152 to expose the conductive features 158. In accordance with some embodiments, conductive structures 166 are formed on the exposed conductive features 158. The formation process of the conductive structures 166 may also include depositing a metal seed layer, forming a patterned plating mask, and plating conductive structures 166 on the exposed conductive features 158. The plating mask is then removed, followed by the etching of the metal seed layer. In some embodiments, a reflow process is then performed to reflow the conductive structures 166. The conductive structures 166 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like.

FIG. 1P and FIG. 1Q illustrate the alignment and the bonding of the redistribution layer 154 on a substrate 168. Referring to FIG. 1P, the redistribution layer 154 is aligned to the substrate 168, with the conductive structures 166 being aligned to the conductive structures 174. In accordance with some embodiments, the substrate 168 may be or may include a package substrate (cored or core-less), an interposer, a package including device dies therein, a device die, a printed circuit board, or the like. In some embodiments, the substrate 168 may include dielectric layers 170 and conductive features 172 disposed in the dielectric layers 170. The conductive features 172 may include horizontal wiring features and conductive vias, which may be formed in the dielectric layers 170 by a damascene process, such as a single damascene process, a dual damascene process, or the like. In some embodiments, conductive structures 174 may be pre-formed on the conductive features 172 of the substrate 168. The conductive structures 174 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like.

Next, in FIG. 1Q, the redistribution layer 154 is placed on the substrate 168, and the conductive structures 166 are bonded to the conductive structures 174 to form conductive structures 176. A reflow process is then performed, so that the redistribution layer 154 is bonded to substrate 168. Afterwards, an underfill material 178 is dispensed into the gap between the redistribution layer 154 and the substrate 168 and surrounding the conductive structures 176 to protect the conductive structures 176, in accordance with some embodiments.

Conductive structures 180 may then be formed on the conductive features 172 to which external connections can be made. Therefore, a semiconductor package structure 182 is formed. The conductive structures 180 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like.

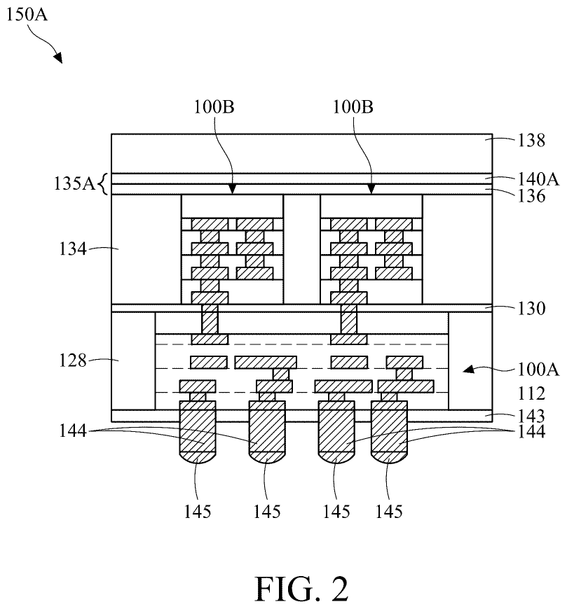

Many variations and/or modifications can be made to embodiments of the disclosure. FIG. 2 is a cross-sectional view of a die structure 150A, in accordance with some embodiments of the present disclosure. As shown in FIG. 2, the die structure 150A has a bonding structure 135A between the semiconductor die 100B and the substrate 138. In some embodiments, the bonding structure 135A includes a bonding layer 136 and a warpage tuning layer 140A. The bonding layer 136 is in contact with the semiconductor die 100B, the dielectric material 134, and the warpage tuning layer 140A. In some embodiments, the bonding layer 136 is pre-formed on the semiconductor dies 100B and the dielectric material 134, and the warpage tuning layer 140A is pre-formed on the substrate 138. Afterwards, the warpage tuning layer 140A is bonded to the bonding layer 136 (such as by hot pressing).

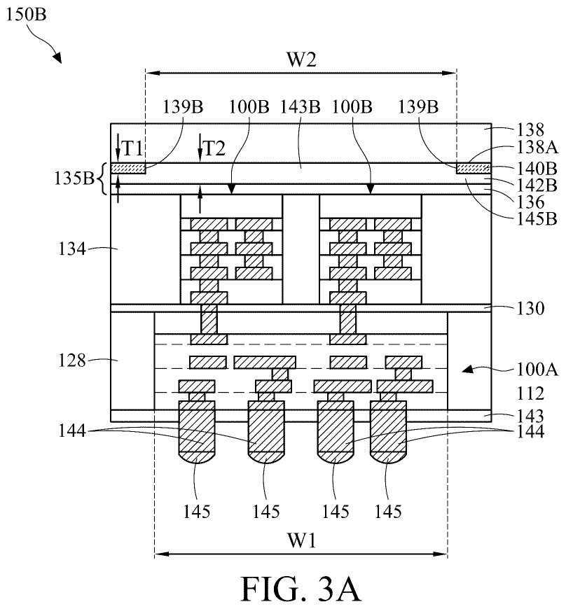

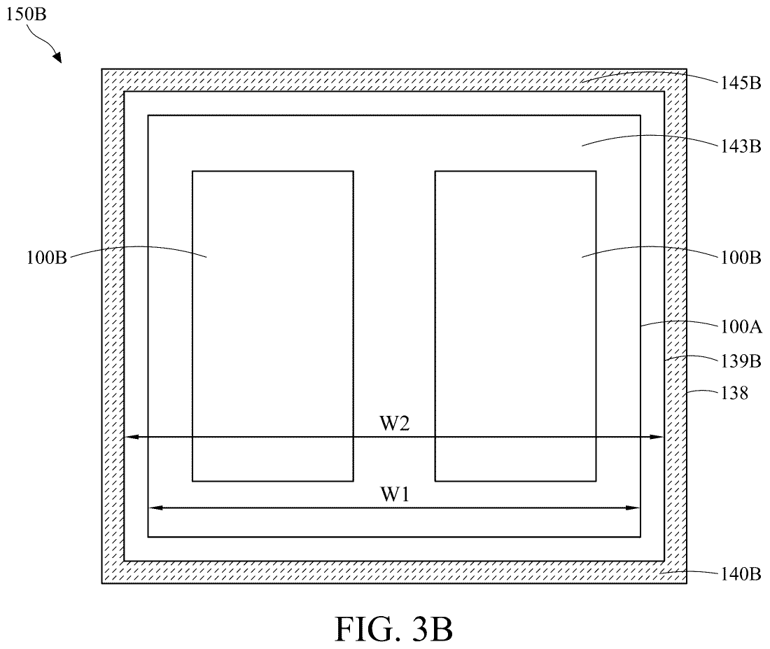

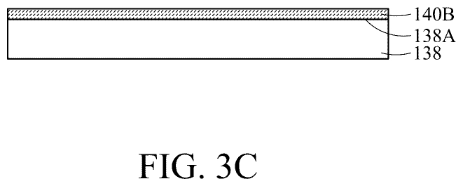

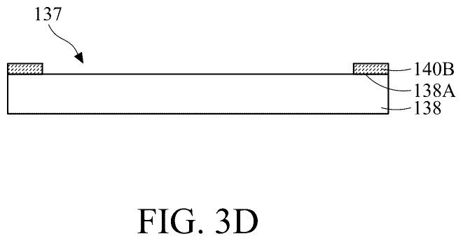

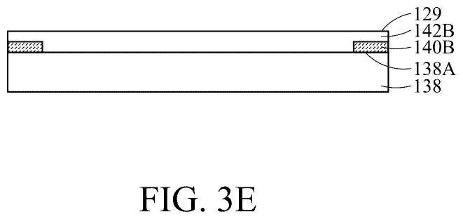

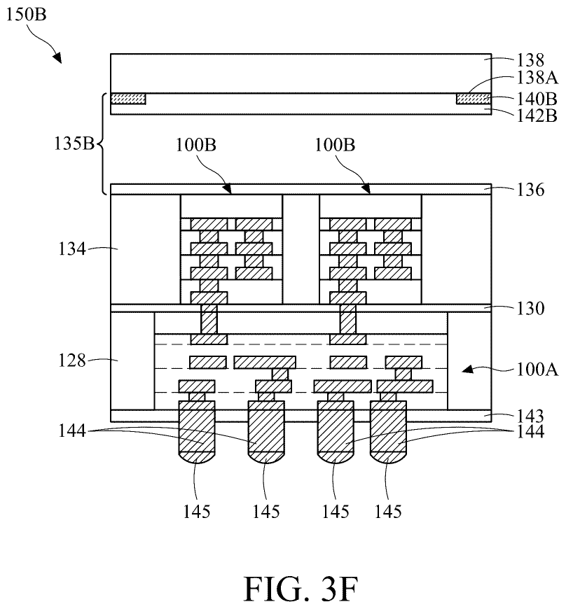

FIG. 3A is a cross-sectional view of a die structure 150B, and FIG. 3B is a top view of the die structure 150B, in accordance with some embodiments of the present disclosure. As shown in FIG. 3A and FIG. 3B, the die structure 150B has a bonding structure 135B between the semiconductor die 100B and the substrate 138. In some embodiments, the bonding structure 135B has a warpage tuning layer 140B disposed on the bottom surface 138A of the substrate 138, and a bonding layer 142B disposed between the warpage tuning layer 140B and the bonding layer 136. In some embodiments, the warpage tuning layer 140B partially covers the bottom surface 138A. For example, the ratio of the area of the warpage tuning layer 140B to the bottom surface 138A is between 0.05 and 1, in accordance with some embodiments. In some embodiments, the bonding layer 142B is in contact with the bottom surface 138A of the substrate 138, and partially surrounded by the warpage tuning layer 140B. In other words, a portion 143B of the bonding layer 142B is disposed in an opening of the warpage tuning layer 140B and surrounded by the warpage tuning layer 140B in a top view. Furthermore, a portion 145B of the bonding layer 142B is between the bonding layer 136 and the warpage tuning layer 140B. In some embodiments, the portion 145B overlaps the warpage tuning layer 140B in the top view.

In such embodiment, the thickness T1 of the warpage tuning layer 140B is less the thickness T2 of the portion 143B. Furthermore, the width W1 of the semiconductor die 100A is less than the width W2 between inner side surfaces 139B of the warpage tuning layer 140B (the width of the portion 143B). In some embodiments, the semiconductor die 100A and the semiconductor dies 100B are surrounded by the warpage tuning layer 140B in the top view. In some embodiments, the portion 143B of the bonding layer 142B is arranged with the warpage tuning layer 140B in a direction parallel to the bottom surface 138A of the substrate 138.

FIG. 3C to FIG. 3F are cross-sectional views of intermediate stages in the manufacturing of a die structure 150B, in accordance with some embodiments. As shown in FIG. 3C, the warpage tuning layer 140B is disposed over the bottom surface 138A of the substrate 138, such as by chemical vapor deposition (CVD), atomic layer deposition (ALD), physical vapor deposition (PVD) a combination thereof, or the like. In FIG. 3D, the warpage tuning layer 140B is patterned utilizing photolithography and etching techniques to form an opening 137 exposing the bottom surface 138A. Afterwards, in FIG. 3E, the bonding layer 142B is disposed over the warpage tuning layer 140B and in the opening 137, such as by chemical vapor deposition (CVD), atomic layer deposition (ALD), physical vapor deposition (PVD) a combination thereof, or the like. Afterwards, a planarization process such as a chemical mechanical polish (CMP), an etch-back process, combinations thereof, or the like is utilized to make the bonding layer 142B having a flat surface 129 in some embodiments. Next, in FIG. 3F, the substrate 138 with the warpage tuning layer 140B and the bonding layer 142B are bonded to the bonding layer 136 to form the die structure 150B, such as by a hot pressing process.

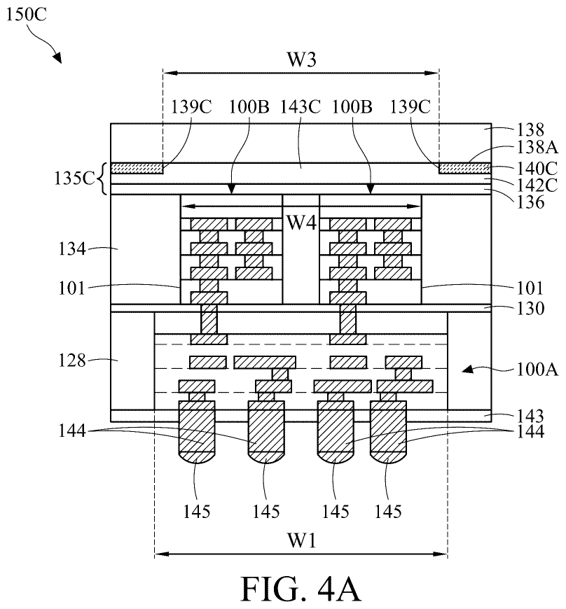

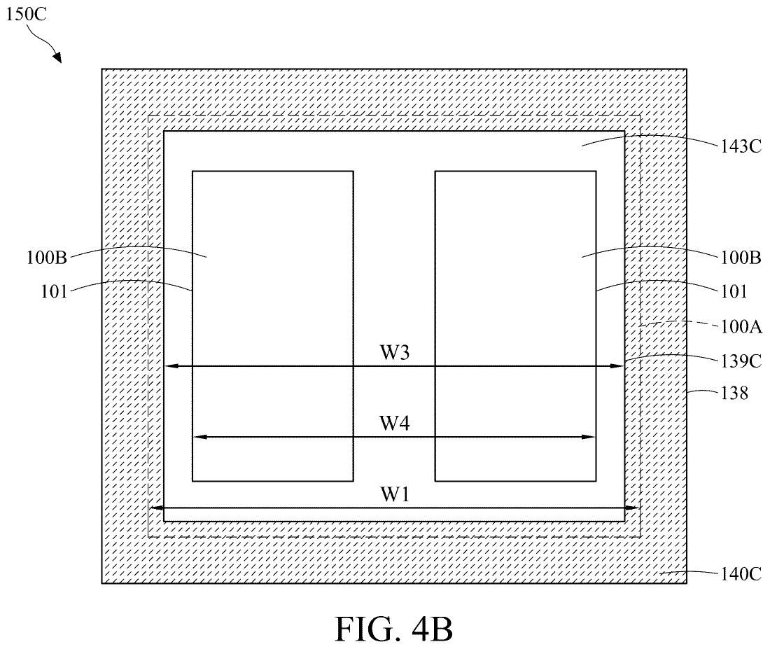

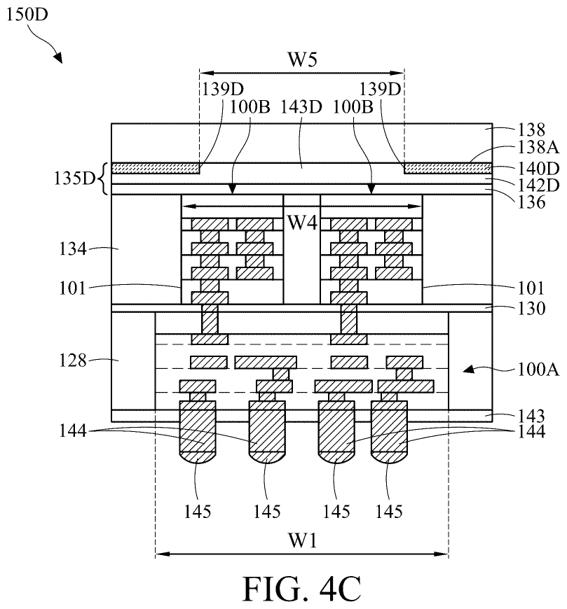

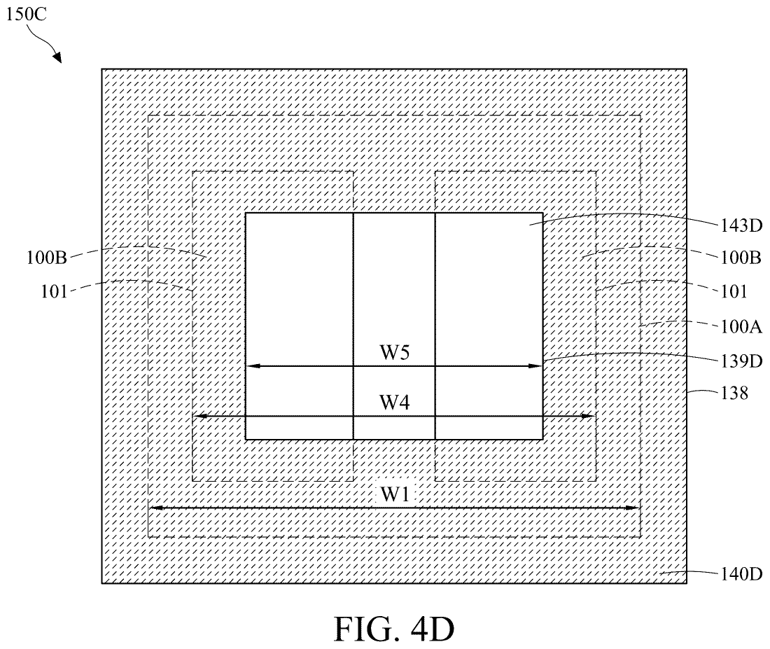

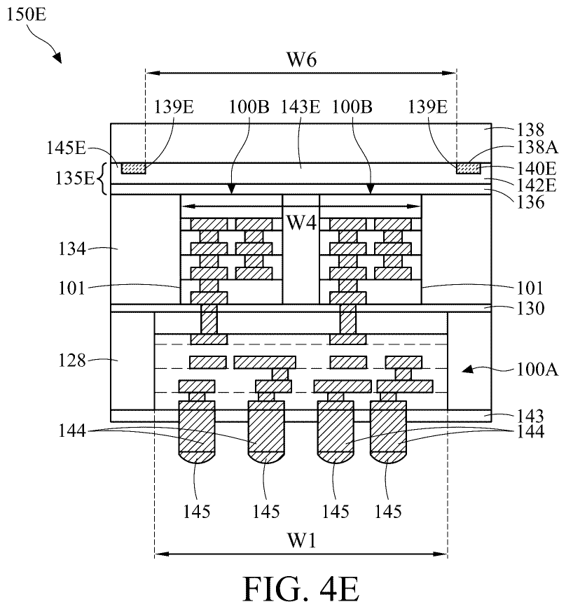

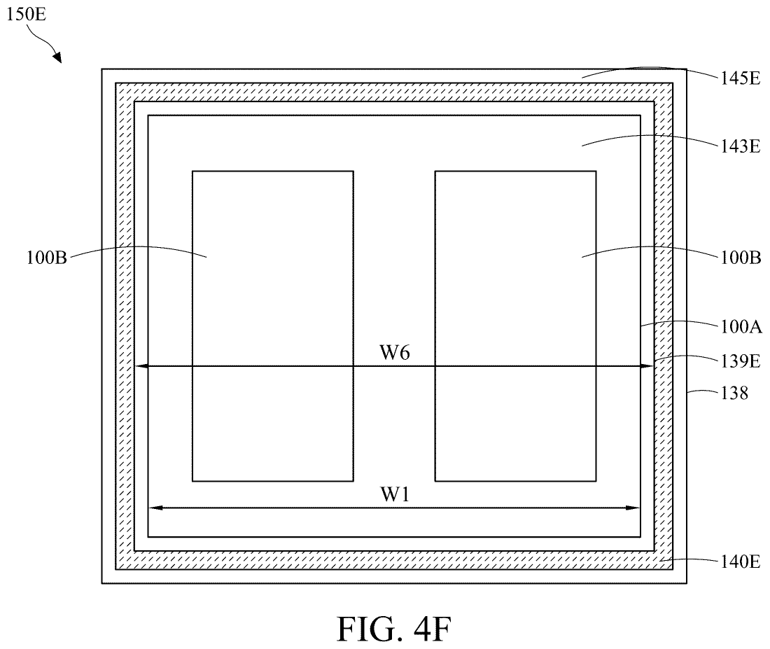

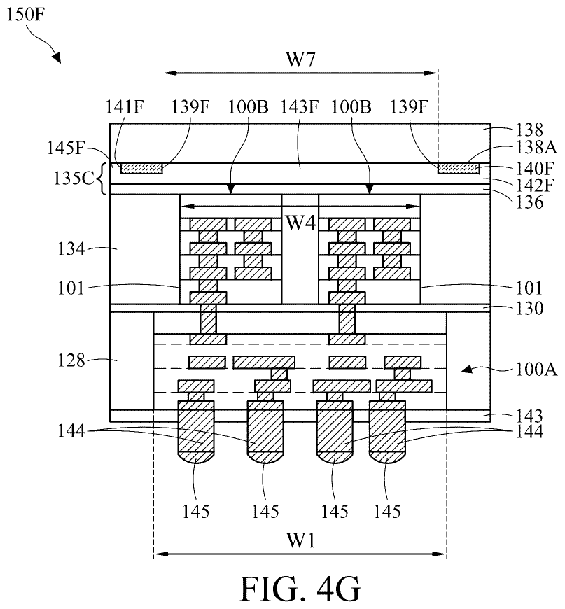

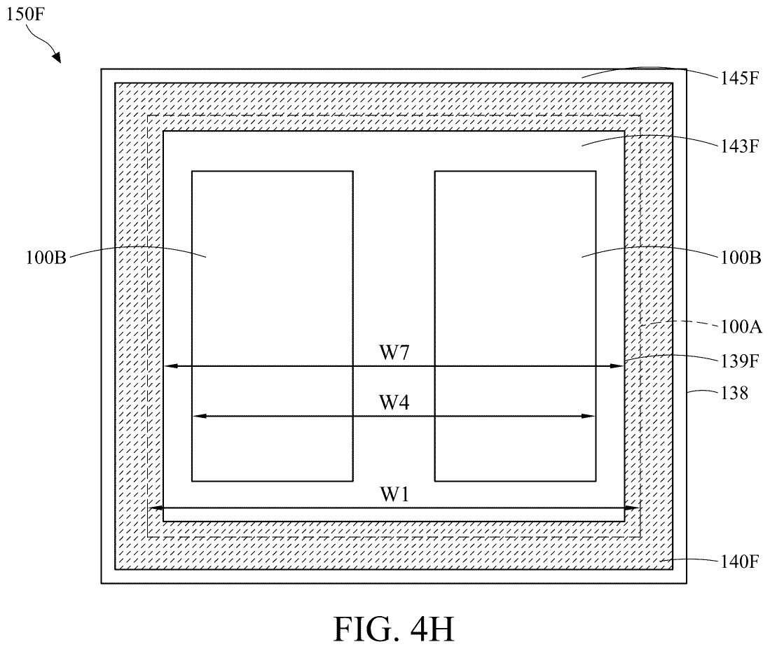

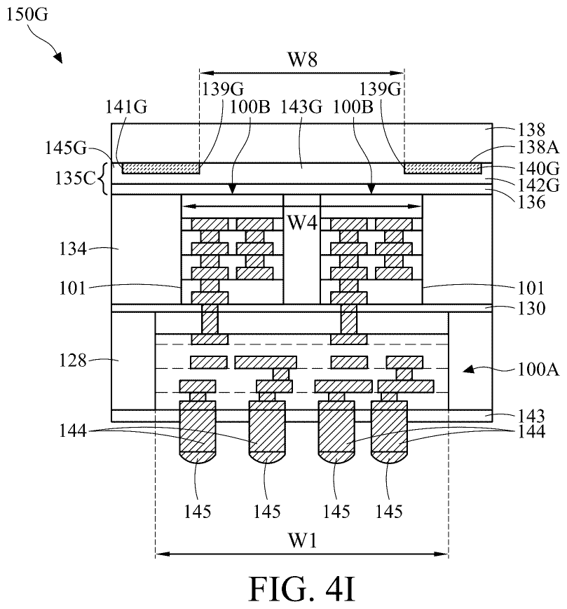

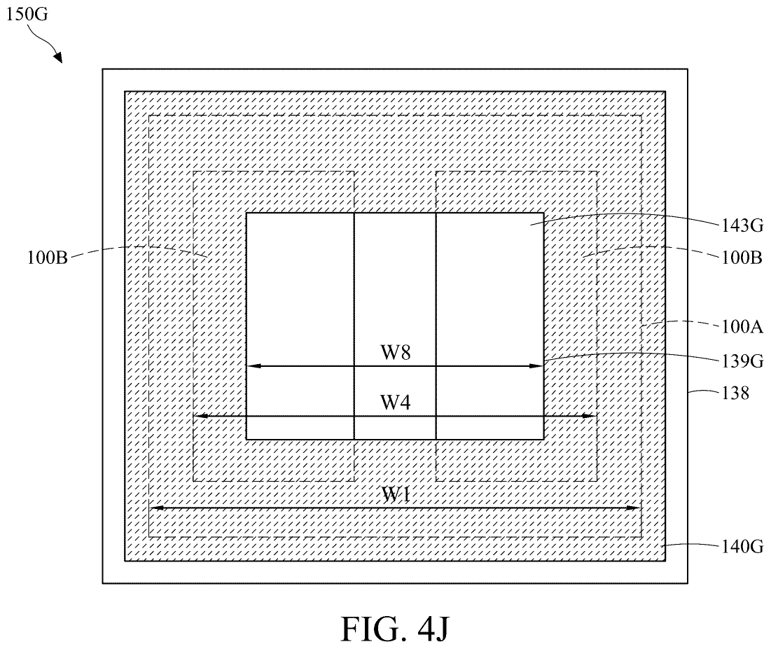

FIG. 4A is a cross-sectional view of a die structure 150C, and FIG. 4B is a top view of the die structure 150C, in accordance with some embodiments of the present disclosure. As shown in FIG. 4A and FIG. 4B, the die structure 150C has a bonding structure 135C between the semiconductor die 100B and the substrate 138. In some embodiments, the bonding structure 135C has a warpage tuning layer 140C disposed on the bottom surface 138A of the substrate 138, and a bonding layer 142C disposed between the warpage tuning layer 140C and the bonding layer 136. In some embodiments, the bonding layer 142C is partially surrounded by the warpage tuning layer 140C.

In some embodiments, the width W1 of the semiconductor die 100A is greater than the width W3 of the portion 143C of the bonding layer 142C between inner side surfaces 139C of the warpage tuning layer 140C. Furthermore, the width W3 is greater than the width W4 between outer side surfaces 101 of the semiconductor dies 100B. As a result, the semiconductor die 100A is partially surrounded by the warpage tuning layer 140C in the top view, and the semiconductor dies 100B are surrounded by the warpage tuning layer 140C in the top view.

FIG. 4C is a cross-sectional view of a die structure 150D, and FIG. 4D is a top view of the die structure 150D, in accordance with some embodiments of the present disclosure. As shown in FIG. 4C and FIG. 4D, the die structure 150D has a bonding structure 135D between the semiconductor die 100B and the substrate 138. In some embodiments, the bonding structure 135D has a warpage tuning layer 140D disposed on the bottom surface 138A of the substrate 138, and a bonding layer 142D disposed between the warpage tuning layer 140D and the bonding layer 136. In some embodiments, the bonding layer 142D is partially surrounded by the warpage tuning layer 140D.

In some embodiments, the width W1 of the semiconductor die 100A and the width W4 between the outer side surfaces 101 of the semiconductor dies 100B are greater than the width W5 of the portion 143D of the bonding layer 142D between inner side surfaces 139D of the warpage tuning layer 140D. As a result, the semiconductor die 100A and the semiconductor dies 100B are partially surrounded by the warpage tuning layer 140D in the top view.

FIG. 4E is a cross-sectional view of a die structure 150E, and FIG. 4F is a top view of the die structure 150E, in accordance with some embodiments of the present disclosure. As shown in FIG. 4E and FIG. 4F, the die structure 150E has a bonding structure 135E between the semiconductor die 100B and the substrate 138. In some embodiments, the bonding structure 135E has a warpage tuning layer 140E disposed on the bottom surface 138A of the substrate 138, and a bonding layer 142E disposed between the warpage tuning layer 140E and the bonding layer 136. In some embodiments, the warpage tuning layer 140E is not exposed from the sidewall of the die structure 150E. Instead, an outer side surface 141E of the warpage tuning layer 140E is in contact with the bonding layer 142E. Therefore, a portion 143E of the bonding layer 142E is surrounded by the warpage tuning layer 140E, and another portion 145E of the bonding layer 142E surrounds the warpage tuning layer 140E in the top view, in accordance with some embodiments.

In some embodiments, the width W1 of the semiconductor die 100A is less than the width W6 of the portion 143E of the bonding layer 142E between inner side surfaces 139E of the warpage tuning layer 140E. As a result, the semiconductor die 100A and the semiconductor dies 100B are surrounded by the warpage tuning layer 140E in the top view.

FIG. 4G is a cross-sectional view of a die structure 150F, and FIG. 4H is a top view of the die structure 150F, in accordance with some embodiments of the present disclosure. As shown in FIG. 4G and FIG. 4H, the die structure 150F has a bonding structure 135F between the semiconductor die 100B and the substrate 138. In some embodiments, the bonding structure 135F has a warpage tuning layer 140F disposed on the bottom surface 138A of the substrate 138, and a bonding layer 142F disposed between the warpage tuning layer 140F and the bonding layer 136. In some embodiments, the warpage tuning layer 140F is not exposed from the sidewall of the die structure 150F. Instead, an outer side surface 141F of the warpage tuning layer 140F is in contact with the bonding layer 142F. Therefore, a portion 143F of the bonding layer 142F is surrounded by the warpage tuning layer 140F, and another portion 145F of the bonding layer 142F surrounds the warpage tuning layer 140F, in accordance with some embodiments.

In some embodiments, the width W1 of the semiconductor die 100A is less than greater the width W7 of the portion 143F of the bonding layer 142F between inner side surfaces 139F of the warpage tuning layer 140F. Furthermore, the width W7 is greater than the width W4 between outer side surfaces 101 of the semiconductor dies 100B. As a result, the semiconductor die 100A is partially surrounded by the warpage tuning layer 140F in the top view, and the semiconductor dies 100B are surrounded by the warpage tuning layer 140F in the top view.

FIG. 4I is a cross-sectional view of a die structure 150G, and FIG. 4J is a top view of the die structure 150G, in accordance with some embodiments of the present disclosure. As shown in FIG. 4I and FIG. 4J, the die structure 150G has a bonding structure 135G between the semiconductor die 100B and the substrate 138. In some embodiments, the bonding structure 135G has a warpage tuning layer 140G disposed on the bottom surface 138A of the substrate 138, and a bonding layer 142G disposed between the warpage tuning layer 140G and the bonding layer 136. In some embodiments, the warpage tuning layer 140G is not exposed from the sidewall of the die structure 150G. Instead, an outer side surface 141G of the warpage tuning layer 140G is in contact with the bonding layer 142G. Therefore, a portion 143G of the bonding layer 142G is surrounded by the warpage tuning layer 140G, and another portion 145G of the bonding layer 142G surrounds the warpage tuning layer 140G, in accordance with some embodiments.

In some embodiments, the width W1 of the semiconductor die 100A and the width W4 between the outer side surfaces 101 of the semiconductor dies 100B are greater than the width W8 of the portion 143G of the bonding layer 142G between inner side surfaces 139G of the warpage tuning layer 140G. As a result, the semiconductor die 100A and the semiconductor dies 100B are partially surrounded by the warpage tuning layer 140G in the top view.

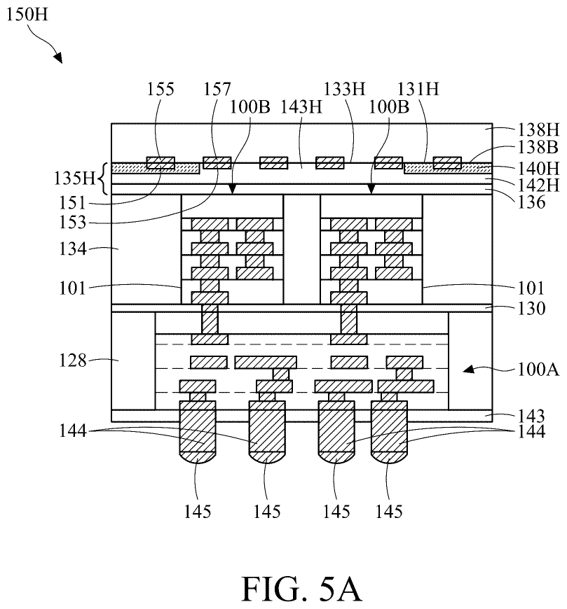

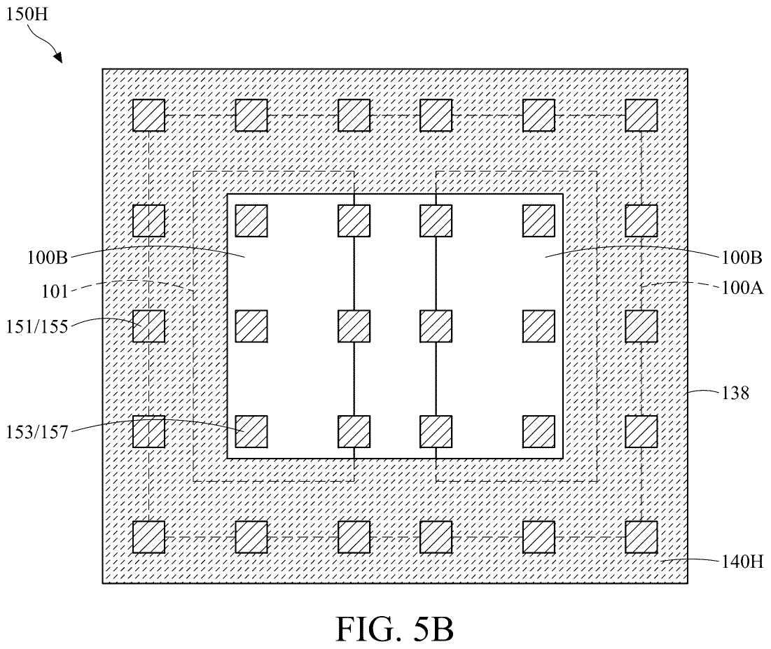

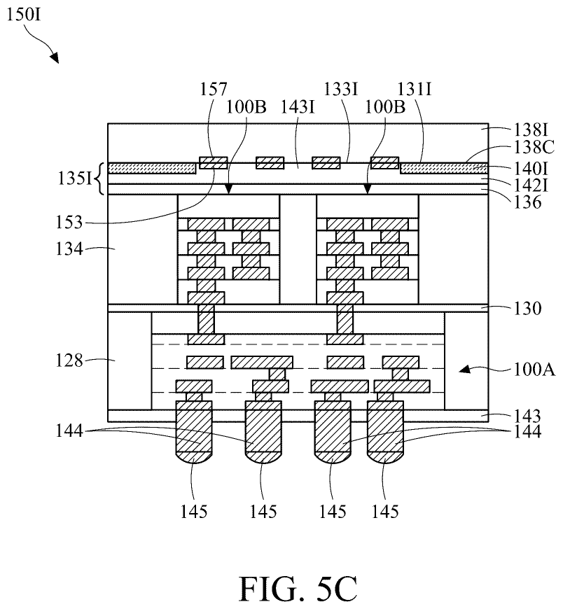

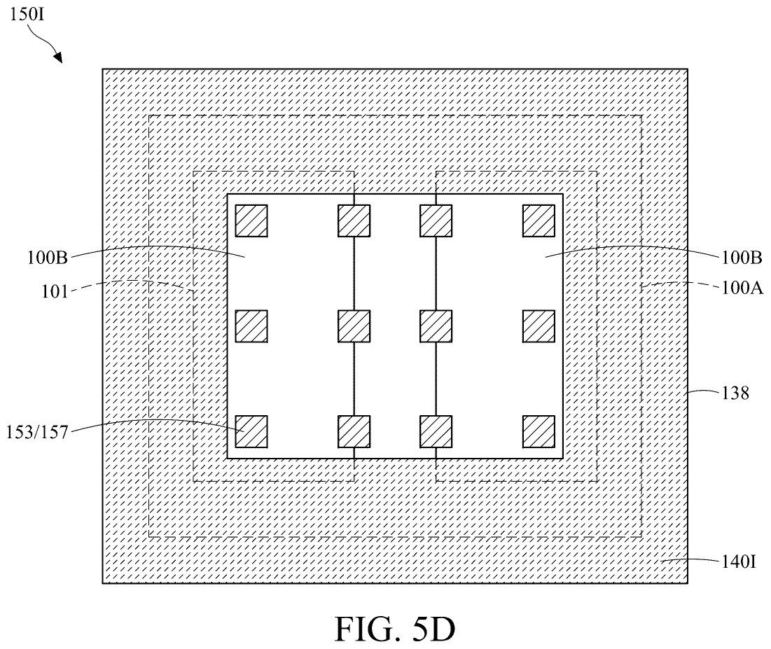

Many variations and/or modifications can be made to embodiments of the disclosure. FIG. 5A is a cross-sectional view of a die structure 150H, and FIG. 5B is a top view of the die structure 150H, in accordance with some embodiments of the present disclosure. As shown in FIG. 5A and FIG. 5B, the die structure 150H has a bonding structure 135H between the semiconductor die 100B and the substrate 138. In some embodiments, the bonding structure 135H has a warpage tuning layer 140H disposed on the bottom surface 138A of the substrate 138, and a bonding layer 142H disposed between the warpage tuning layer 140H and the bonding layer 136. In some embodiments, a portion 143H of the bonding layer 142H is surrounded by the warpage tuning layer 140H.

In some embodiments, the substrate 138 is bonded to the warpage tuning layer 140H and the bonding layer 142H by hybrid bonding, which includes metal-to-metal bonding and dielectric-to-dielectric bonding, without using any adhesive material (e.g., die attach film). In some embodiments, bonding features 151 are disposed in the warpage tuning layer 140H and exposed from a top surface 131H of the warpage tuning layer 140H which faces the bottom surface 138B of the substrate 138H. In some embodiments, bonding features 153 are disposed in the portion 143H of the bonding layer 142H and exposed from a top surface 133H of the bonding layer 142H which faces the bottom surface 138B of the substrate 138H. In some embodiments, bonding features 155 and 157 are disposed in the substrate 138H and exposed from the bottom surface 138B of the substrate 138H. The bonding features 155 overlap the bonding features 151 in the top view and in direct contact with the bonding features 151, and bonding features 157 overlap the bonding features 153 in the top view and in direct contact with the bonding features 153.

The bonding may include a pre-bonding and an annealing. During the pre-bonding, a small pressing force is applied to press the substrate 138H against the warpage tuning layer 140H and the bonding layer 142H. The pre-bonding is performed at a low temperature, such as room temperature, and after the pre-bonding, the warpage tuning layer 140H and the bonding layer 142H are bonded to the substrate 138H. The bonding strength is then improved in a subsequent annealing step. After the annealing, direct bonds such as fusion bonds are formed, bonding the substrate 138H to the warpage tuning layer 140H and the bonding layer 142H. The bonds may be covalent bonds between the material of the substrate 138H and the material of the warpage tuning layer 140H and the bonding layer 142H. Further, during the annealing, the material of the bonding features 151, 153, 155, and 157 may be intermingled so that metal-to-metal bonds are also formed. Hence, the resulting bonds between the substrate 138H and the warpage tuning layer 140H and the bonding layer 142H are hybrid bonds that include both dielectric-to-dielectric bonds and metal-to-metal bonds, in accordance with some embodiments.

In some embodiments, the bonding features 151, 153, 155, and 157 may include a multi-layer structure, such as including a main layer and a barrier layer surrounding the bottom and sidewalls of the main layer. The main layer may include copper or other low-resistance material such as copper, a copper alloy, silver, gold, tungsten, cobalt, aluminum, nickel, a combination thereof, or the like, and the barrier layer may include titanium, titanium nitride, tantalum, tantalum nitride, combinations thereof, or the like. The formation of the bonding features 151, 153, 155, and 157 may include recessing (e.g. etching) the substrate 138H, the warpage tuning layer 140H, and the bonding layer 142H for forming openings for the bonding features 151, 153, 155, and 157. Materials of the bonding features 151, 153, 155, and 157 may then be deposited in the openings, such as by electroplating, electroless plating, CVD, ALD, PVD, combinations thereof, or the like. Excess material of the bonding features 151, 153, 155, and 157 may be removed by a planarization process, such as CMP or grinding.

FIG. 5C is a cross-sectional view of a die structure 150I, and FIG. 5D is a top view of the die structure 150I, in accordance with some embodiments of the present disclosure. As shown in FIG. 5C and FIG. 5D, there is no bonding features overlapping the warpage tuning layer 140I in the top view, and only bonding features 153 and 157 are disposed in the portion 143I of the bonding layer 142I and the substrate 138I, respectively. The bonding features 153 are exposed from the top surface 133I of the bonding layer 142I, and the bonding features 157 are exposed from the bottom surface 138C of the substrate 138I. The bonding features 153 are bonded to the bonding features 157 by metal-to-metal bonds, and the warpage tuning layer 140I and the bonding layer 142I are bonded to the substrate 138I by dielectric-to-dielectric bonds, so a hybrid bonding is achieved.

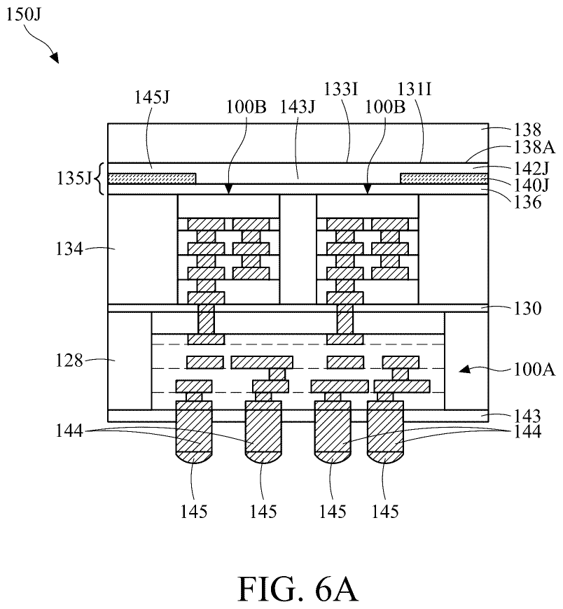

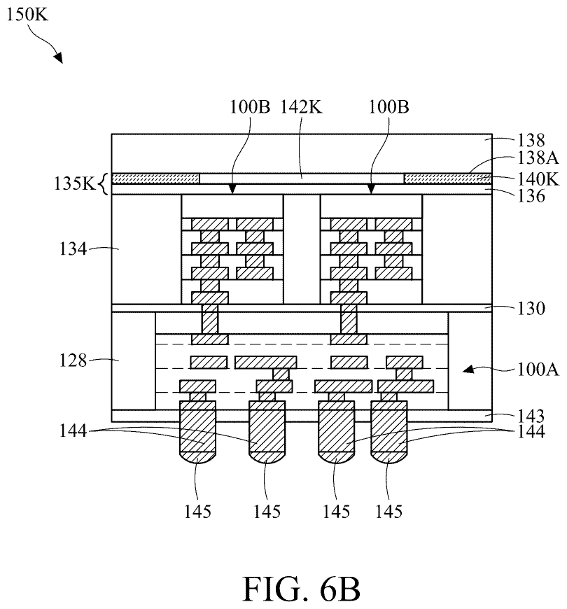

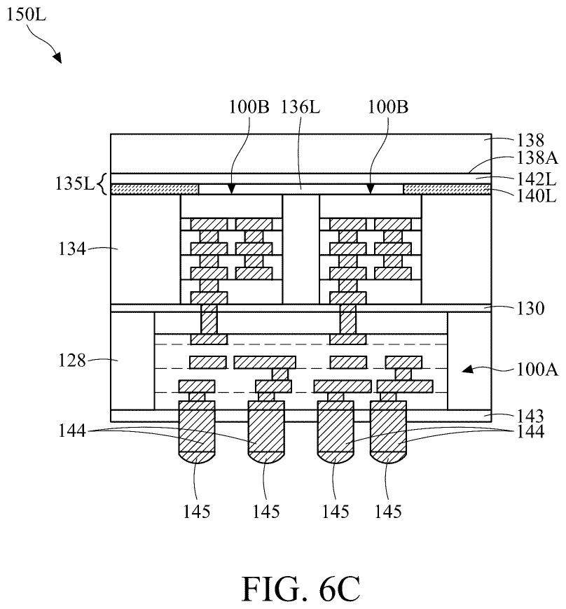

FIG. 6A is a cross-sectional view of a die structure 150J, in accordance with some embodiments of the present disclosure. The die structure 150J has a bonding structure 135J between the semiconductor die 100B and the substrate 138. In some embodiments, the bonding structure 135J has a bonding layer 136 disposed on the semiconductor die 100B, a bonding layer 142J disposed on the bottom surface 138A of the substrate 138, and a warpage tuning layer 140J disposed between the bonding layer 136 and the bonding layer 142J. In some embodiments, a portion 143J of the bonding layer 142J is surrounded by the warpage tuning layer 140J and in contact with the bonding layer 136. In some embodiments, the substrate 138 and the warpage tuning layer 140J are separated by a portion 145J of the bonding layer 142J.

FIG. 6B is a cross-sectional view of a die structure 150K, in accordance with some embodiments of the present disclosure. The die structure 150K has a bonding structure 135K between the semiconductor die 100B and the substrate 138. In some embodiments, the bonding structure 135K has a bonding layer 136 disposed on the semiconductor die 100B, a warpage tuning layer 140K and a bonding layer 142K disposed on the bottom surface 138A of the substrate 138. In some embodiments, a portion of the bonding layer 142K is surrounded by the warpage tuning layer 140K and in contact with the bonding layer 136. In some embodiments, thicknesses of the warpage tuning layer 140K and the bonding layer 142K are substantially identical. In some embodiments, the warpage tuning layer 140K and the bonding layer 142K are in contact with the bonding layer 136 and the bottom surface 138A of the substrate 138.

FIG. 6C is a cross-sectional view of a die structure 150L, in accordance with some embodiments of the present disclosure. The die structure 150L has a bonding structure 135L between the semiconductor die 100B and the substrate 138. In some embodiments, the bonding structure 135L has a bonding layer 136L and a warpage tuning layer 140L disposed on the semiconductor die 100B, and a bonding layer 142L disposed on the bottom surface 138A of the substrate 138. In some embodiments, a portion of the bonding layer 136L is surrounded by the warpage tuning layer 140L and in contact with the bonding layer 142L. In some embodiments, thicknesses of the bonding layer 136L and the warpage tuning layer 140L are substantially identical. In some embodiments, the bonding layer 136L and the warpage tuning layer 140L are in contact with the bonding layer 142L. In some embodiments, the bonding layer 136L and the warpage tuning layer 140L are separated from the substrate 138 by the bonding layer 142L.

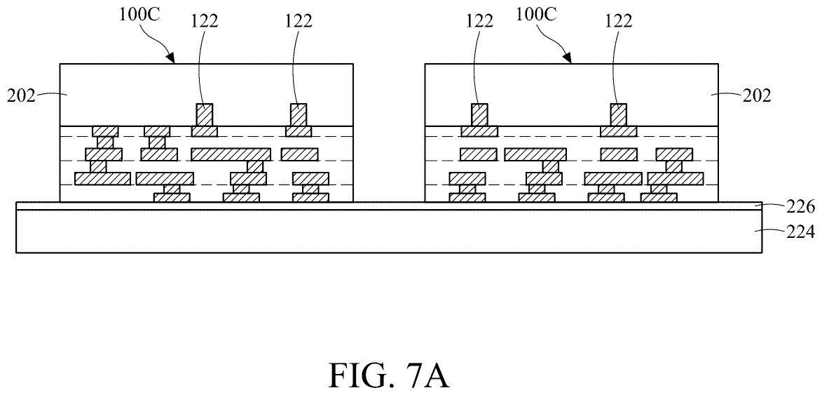

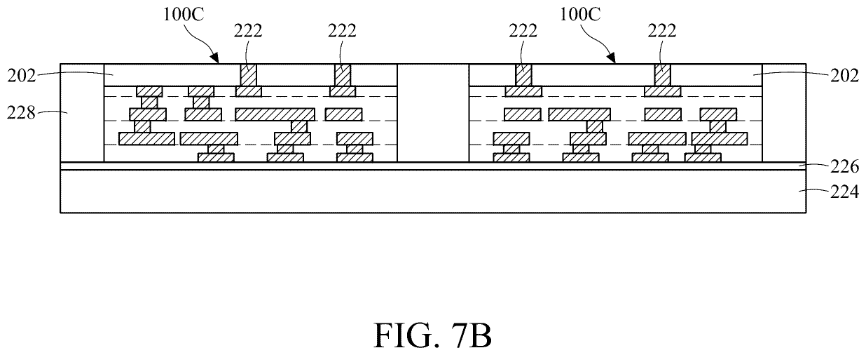

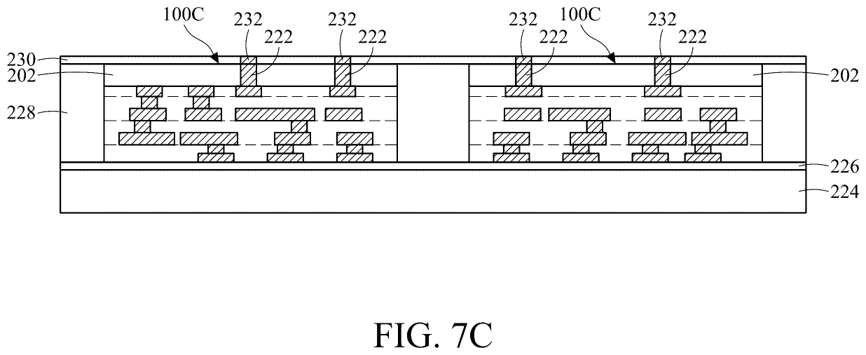

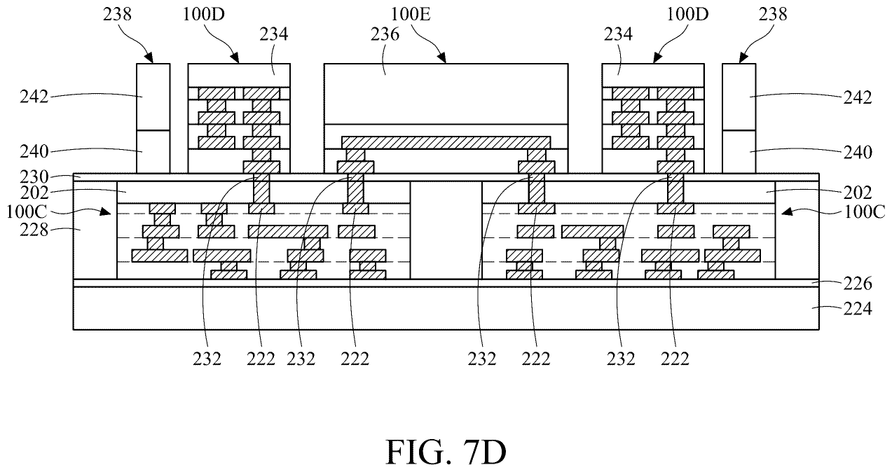

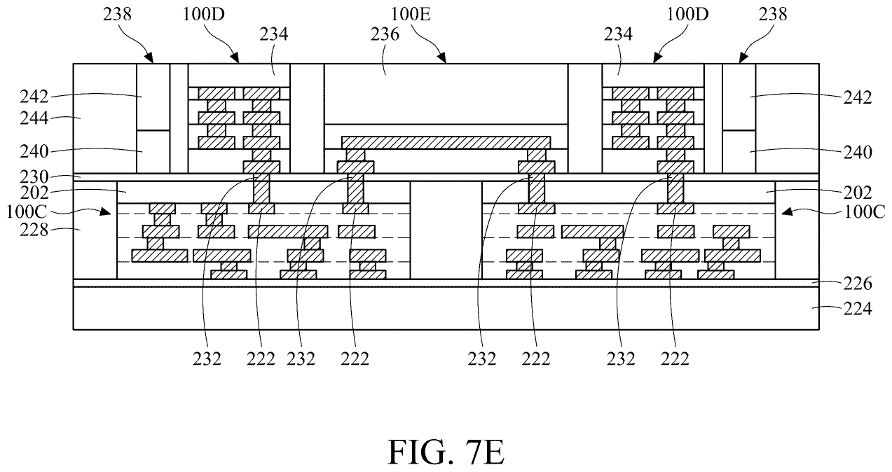

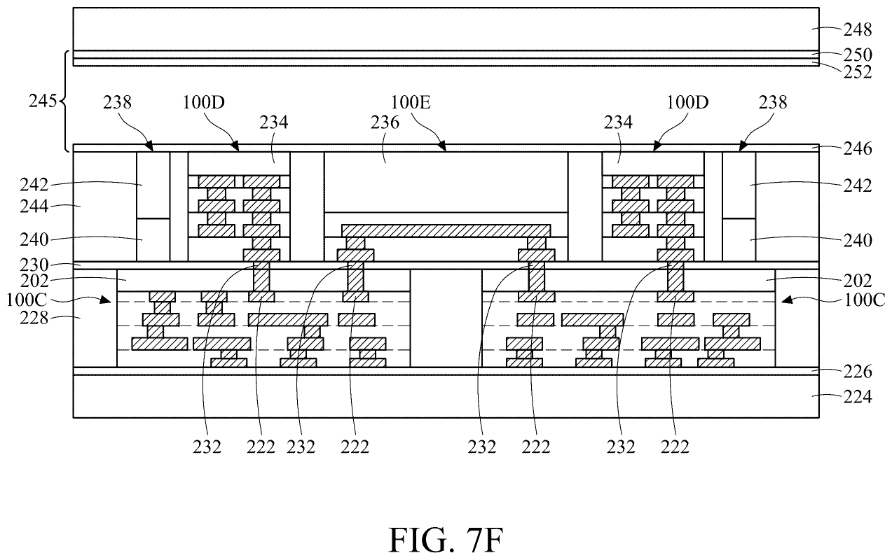

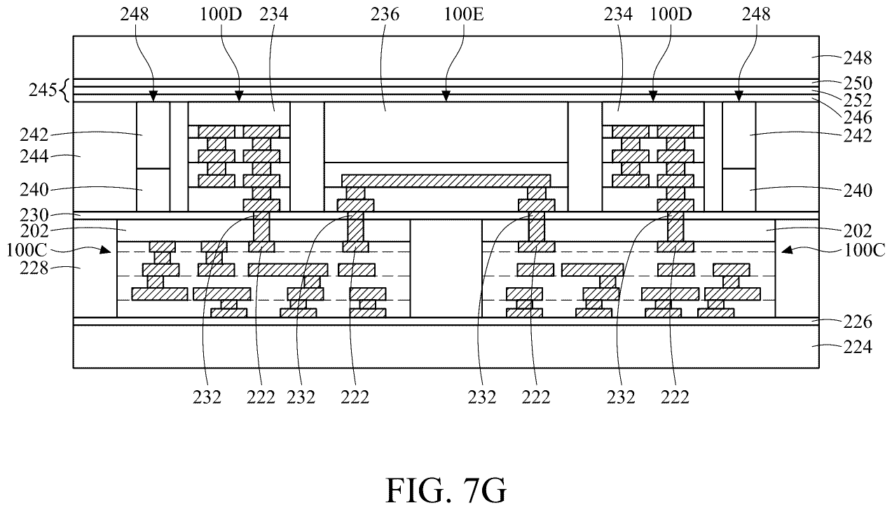

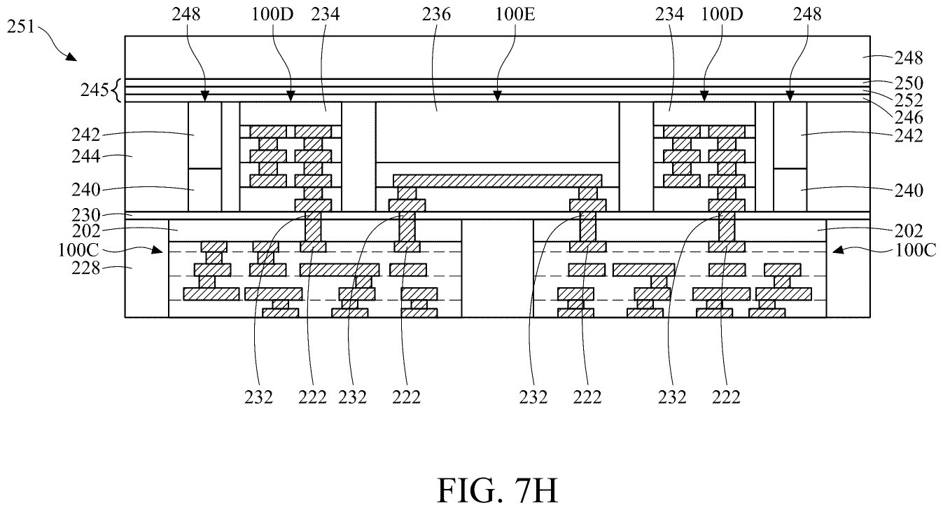

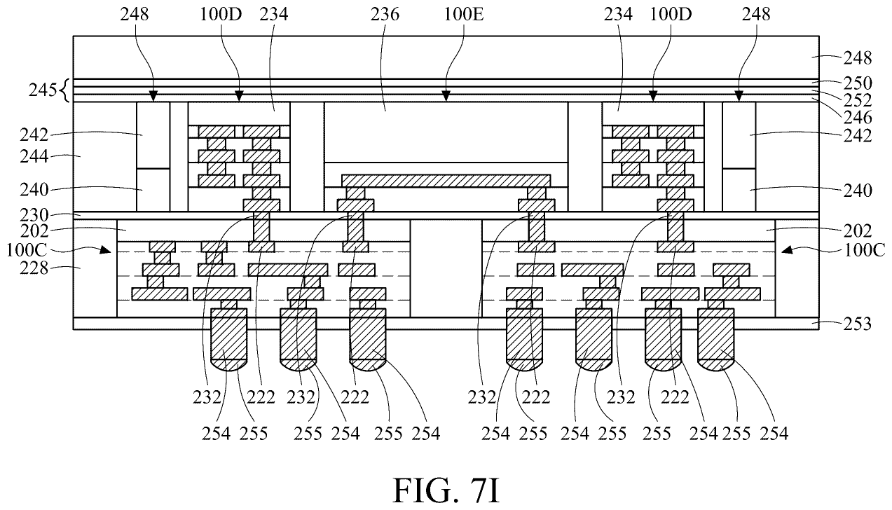

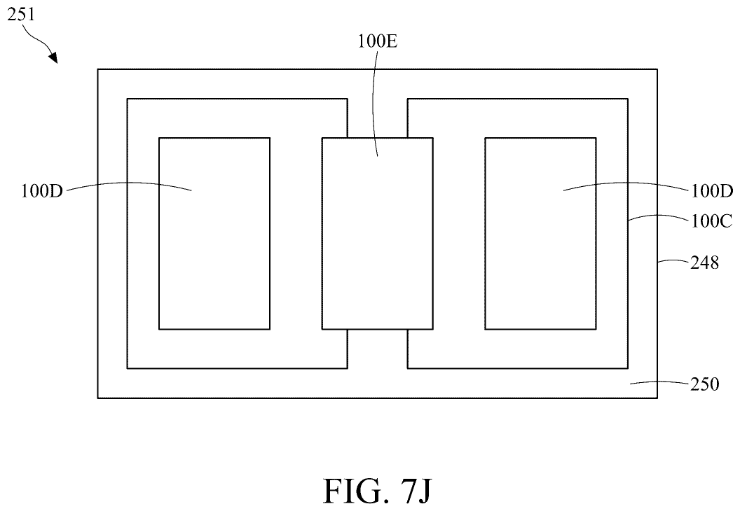

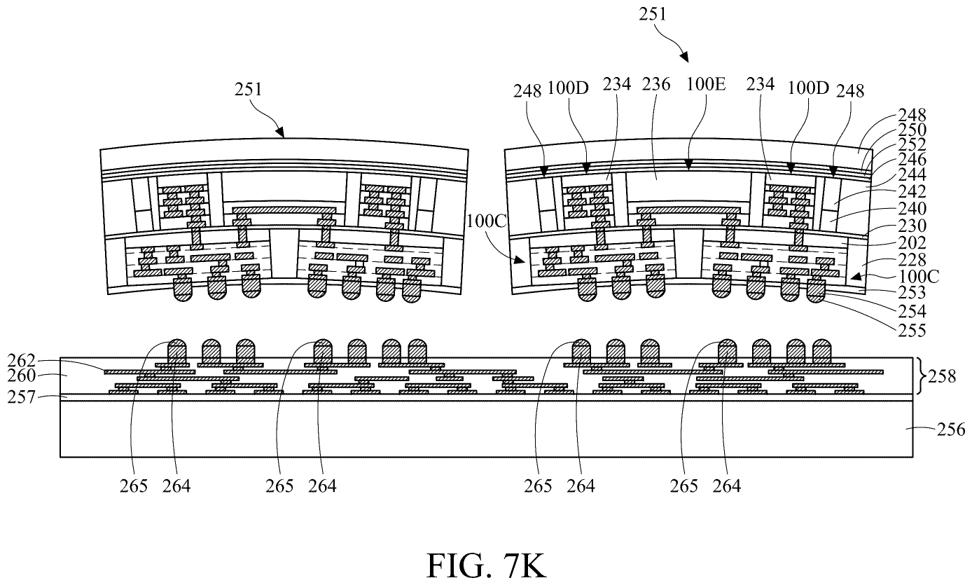

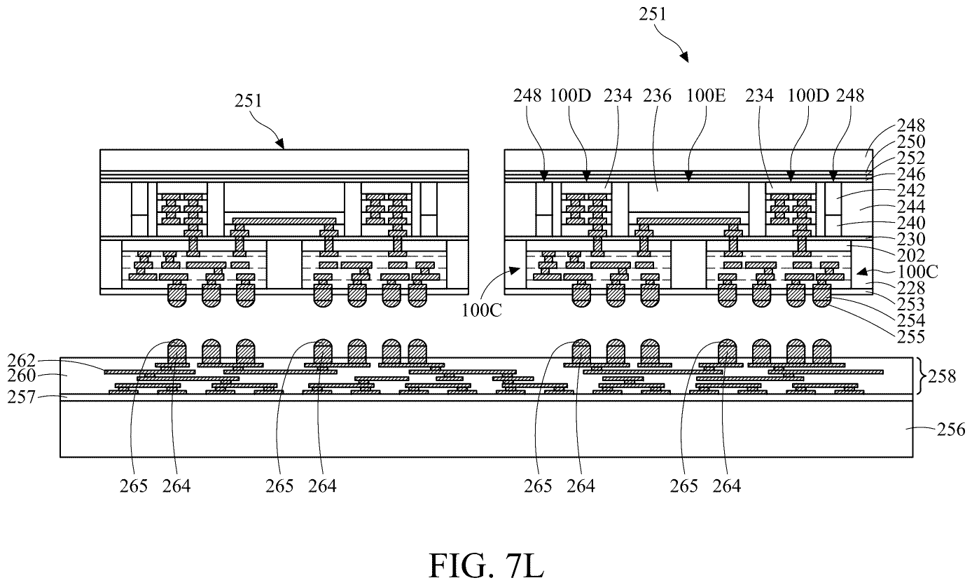

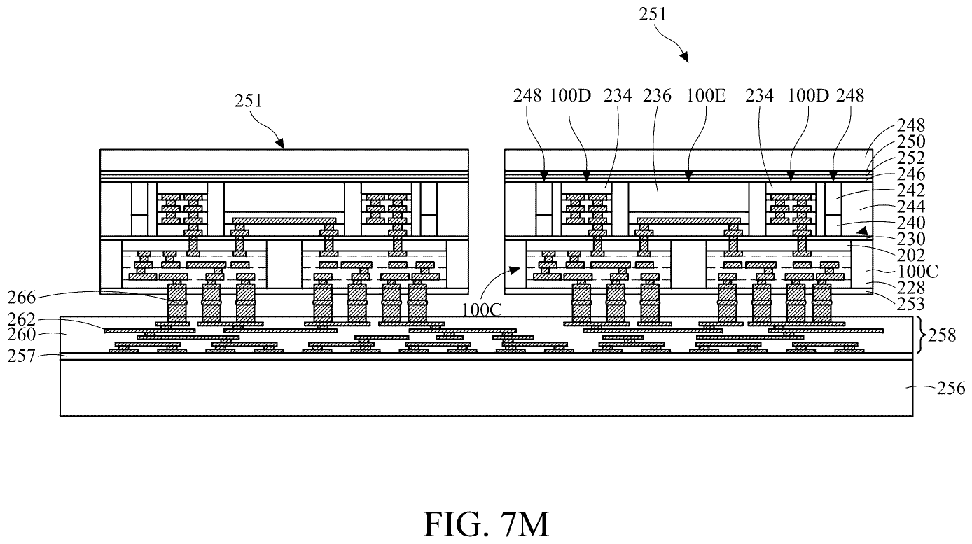

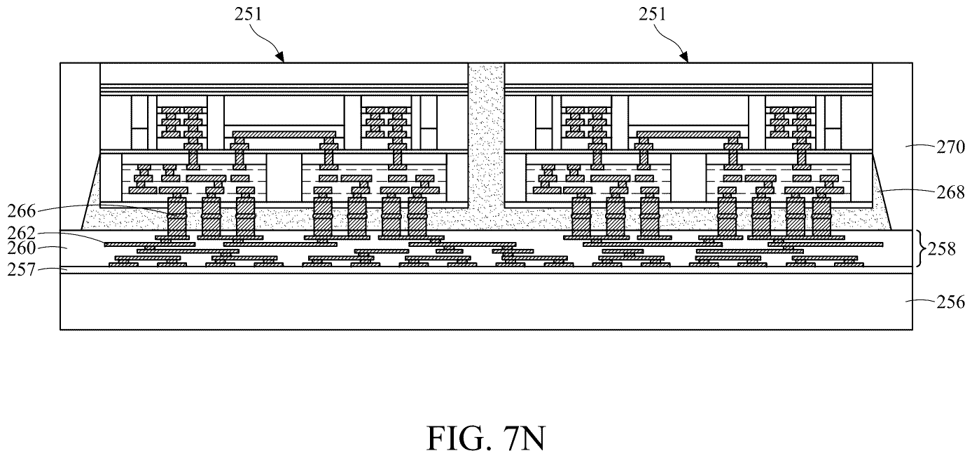

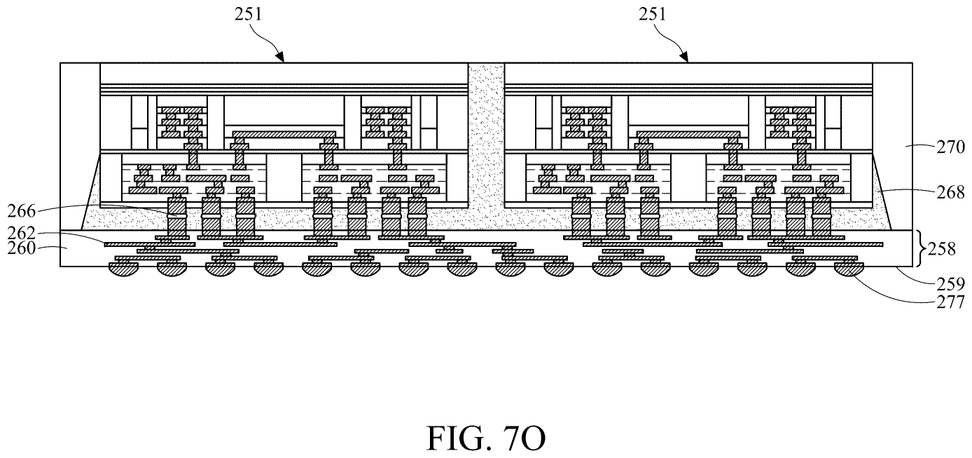

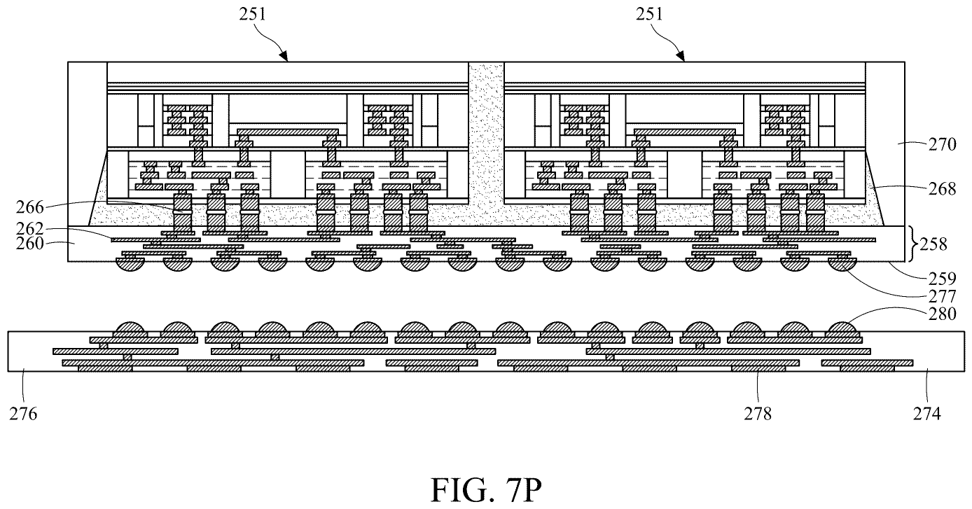

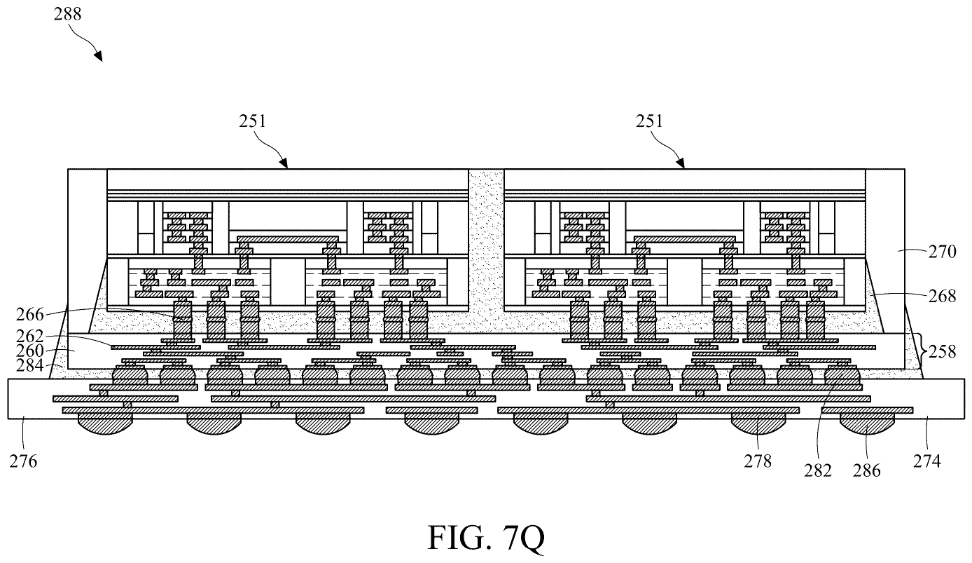

FIG. 7A to FIG. 7I are cross-sectional views of intermediate stages in the manufacturing of a semiconductor package structure 288, in accordance with some embodiments. As shown in FIG. 7A, a bonding layer 226 is disposed over the carrier substrate 224, and semiconductor dies 100C are disposed over the bonding layer 226. FIG. 7A illustrates two semiconductor dies 100C as an example, and it should be noted that any other numbers of semiconductor dies 100C may be applied in other embodiments. The semiconductor die 100C may be identical or similar to the semiconductor die 100A described above.

In FIG. 7B, a dielectric material 228 is applied over the bonding layer 226 to surround the semiconductor dies 100C. Afterwards, the substrates 202 and the dielectric material 228 are thinned to expose conductive vias 222 of the semiconductor dies 100C. In FIG. 7C, a dielectric layer 230 is disposed over the semiconductor dies 100C and the dielectric material 228. Afterwards, bonding pads 232 are formed in the dielectric layer 230 and in contact with the conductive vias 222.

In FIG. 7D, semiconductor dies 100D and a semiconductor die 100E are disposed over the dielectric layer 230. In some embodiments, each of the semiconductor dies 100D are disposed above one of the semiconductor dies 100C, and the semiconductor die 100E extends across and electrically connected to the two semiconductor dies 100C.

Optionally, dummy semiconductor devices 238 are attached to the dielectric layer 230. Any desired quantity of dummy semiconductor devices 238 may be attached to the dielectric layer 230, such that each dummy semiconductor device 238 overlaps at least one semiconductor die 100C. In some embodiments, the dummy semiconductor devices 238 may be disposed around the semiconductor dies 100D and the semiconductor die 100E. In some embodiments, when the semiconductor dies 100C are wider than the semiconductor dies 100D and the semiconductor die 100E, including the dummy semiconductor devices 238 can help reduce the size of gaps between the semiconductor dies 100D and the semiconductor die 100E, thereby improving structural reliability.

The dummy semiconductor devices 238 are substantially free of any active or passive devices. The dummy semiconductor devices 238 may each include a substrate 242 and a dielectric layer 240. The substrate 242 may be formed of a similar material as the substrate 102, except the substrate 242 may be undoped. The dielectric layer 240 may be formed of a similar material as the dielectric layer 106.

The dummy semiconductor devices 238 may be attached to the dielectric layer 230 by placing the dummy semiconductor devices 238 on the dielectric layer 230, and then bonding the dummy semiconductor devices 238 to the dielectric layer 230. The dummy semiconductor devices 238 may be placed by, e.g., a pick-and-place process. The bonding process may include fusion bonding, dielectric bonding, or the like. For example, The dielectric layers 240 of the dummy semiconductor devices 238 may be directly bonded to the dielectric layer 230 through dielectric-to-dielectric bonding, without using any adhesive material (e.g., die attach film). The bonding may include a pre-bonding and an annealing, in a similar manner as the bonding of the semiconductor dies 100D or the semiconductor dies 100E to the dielectric layer 230. In some embodiments, the dummy semiconductor devices 238 are bonded to the dielectric layer 230 by the same bonding process as the semiconductor dies 100D or the semiconductor dies 100E.

As shown in FIG. 7E, a dielectric material 244 is provided to surround the semiconductor dies 100D and 100E and the dummy semiconductor devices 238 and fill the gaps between the semiconductor dies 100D and 100E and the dummy semiconductor devices 238. Afterwards, a planarization process is performed to expose the semiconductor dies 100D and 100E and the dummy semiconductor devices 238 from the dielectric material 244.

In FIG. 7F, a bonding layer 246 is attached to the semiconductor dies 100D and 100E, the dummy semiconductor devices 238, and the dielectric material 244. A substrate 248 having a warpage tuning layer 250 and a bonding layer 252 disposed thereon is provided. The bonding layer 246, the warpage tuning layer 250, and the bonding layer 252 are referred to as a bonding structure 245. In FIG. 7G, the substrate 248 is bonded to the semiconductor dies 100D and 100E, the dummy semiconductor devices 238, and the dielectric material 244 through the bonding structure 245. In FIG. 7H, the carrier substrate 224 and the bonding layer 226 are removed. Afterwards, a singulation process is performed form a singulated die structure 251.

In FIG. 7I, a passivation layer 253 is disposed on the semiconductor dies 100C and the dielectric material 228, and then conductive structures 254 and 255 are formed on the semiconductor dies 100C. The conductive structures 254 extends through the passivation layer 253.

FIG. 7J is a top view of the die structure 251, in accordance with some embodiments. As shown in FIG. 7J, each of the semiconductor dies 100D is disposed over each of the semiconductor dies 100C, and the semiconductor die 100E partially overlaps the two semiconductor dies 100C.

FIG. 7K to FIG. 7Q are cross-sectional views of intermediate stages in the manufacturing of a semiconductor package structure 288, in accordance with some embodiments. As shown in FIG. 7K, the temperature is reduced to room temperature (such as about 25° C.) to preform subsequent processes. Since the warpage tuning layer 250 has compressive film stress, the curvature of the substrate 248 is increased as the temperature is reduced to the room temperature. In some embodiments, a carrier substrate 256 with a release film 257 and a redistribution layer 258 is provided, and the die structures 251 may be placed over the redistribution layer 258 by, e.g., a pick-and-place process.

In some embodiments, the redistribution layer 258 includes a plurality of dielectric layers 260 and a plurality of conductive features 262 formed in the dielectric layers 260. Conductive structures 264 and 265 are disposed over the redistribution layer 258, and the conductive structures 264 are electrically connected to the conductive features 262 and the conductive structures 265.

In FIG. 7L, the temperature is raised for performing a bonding process, and the curvature of the substrate 248 is changed to be substantially flat in FIG. 7L by the warpage tuning layer 250 having compressive film stress, so the curvature of the substrate 248 in FIG. 7L is less than the curvature of the substrate 248 in FIG. 7K, which not only stabilizes the die structure 251 but also reduces the defects associated with the warpage. In some embodiments, the temperature is raised from room temperature to a high temperature between about 100° C. and about 400° C.

In FIG. 7M, after the temperature is raised, the conductive structures 255 may be bonded to the conductive structures 265 in accordance with some embodiments. In some embodiments, the conductive structures 254, 255, 264, and 265 may be collectively referred to conductive structures 266.

As shown in FIG. 7N, after the die structures 251 are placed over the redistribution layer 258, an underfill material 268 is dispensed between the die structures 251 and the redistribution layer 258 to surround the conductive structures 266 and the die structures 251. Next, a molding layer 270 is provided over the redistribution layer 258 to surround the die structures 251 and the underfill material 268. Planarization process is then performed to expose top surfaces of the die structures 251 from the molding layer 270.

In FIG. 7O, the carrier substrate 256 is removed from the redistribution layer 258 by removing the release film 257. Afterwards, conductive structures 272 are formed on the bottom surface 259 of the redistribution layer 258 and connected to the conductive features 262. In FIG. 7P, a substrate 274 having is provided. The substrate includes dielectric layers 276 and conductive features 278 disposed in the dielectric layers 276. Conductive structures 280 are disposed over the substrate 274 and electrically connected to the conductive features 278. In FIG. 7Q, the redistribution layer 258 is bonded to the substrate 274 by bonding the conductive structures 272 to the conductive structures 280. The conductive structures 272 and 280 are referred to as conductive structures 282. Next, underfill material is dispensed between the redistribution layer 258 and the substrate 274 to surround the conductive structures 282. Conductive structures 286 are provided on the substrate 274 to electrically connect to the conductive features 278 to form the semiconductor package structure 288.

In summary, die structures having a warpage tuning layer are provided in some embodiments of the present disclosure. The warpage tuning layer has compressive film stress, which counteracts the warpage induced by temperature variations during the manufacturing process. This approach not only stabilizes the die structure but also reduces the defects associated with the warpage. Consequently, the overall yield and reliability of the manufacturing process are improved.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In some embodiments, a die structure is provided. The die structure includes a first semiconductor die, a second semiconductor die disposed over the first semiconductor die, a first bonding layer disposed over the second semiconductor die, a high-k layer disposed over the bonding layer, and a substrate disposed over the high-k layer. The compressive film stress of the first bonding layer is less than the compressive film stress of the high-k layer.

In some embodiments, a die structure is provided. The die structure includes a first semiconductor die, a second semiconductor die disposed over the first semiconductor die, a first bonding layer disposed over the second semiconductor die, a second bonding layer disposed over the first bonding layer, a high-k layer disposed over the first bonding layer, and a substrate disposed over the high-k layer. A first portion of the first bonding layer is surrounded by the high-k layer in a top view.

In some embodiments, a method for forming a semiconductor package structure is provided. The method includes disposing a second semiconductor die over a first semiconductor die. The method includes attaching a substrate to the second semiconductor die using a bonding structure. The method includes heating the bonding structure to a first temperature to form a die structure. The method includes placing the die structure over an interposer substrate at a second temperature. The method includes bonding the die structure to the interposer substrate at a third temperature. The substrate has a first curvature at the first temperature. The second temperature is lower than the first temperature. The substrate has a second curvature at the second temperature. The second curvature is greater than the first curvature. The third temperature is higher than the second temperature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A die structure, comprising:
a first semiconductor die;
a second semiconductor die disposed over the first semiconductor die;
a first bonding layer disposed over the second semiconductor die;
a high-k layer disposed over the first bonding layer; and
a substrate disposed over the high-k layer, wherein a compressive film stress of the first bonding layer is less than a compressive film stress of the high-k layer.

2. The die structure as claimed in claim 1, wherein a ratio of an area of the high-k layer to an area of the substrate is between 0.05 and 1.

3. The die structure as claimed in claim 1, wherein a portion of the first bonding layer is arranged with the high-k layer in a direction parallel to a bottom surface of the substrate.

4. The die structure as claimed in claim 1, wherein the high-k layer comprises conductive material.

5. The die structure as claimed in claim 1, wherein the high-k layer comprises insulating material.

6. The die structure as claimed in claim 1, further comprising a second bonding layer disposed between the first bonding layer and the high-k layer.

7. A die structure, comprising:
a first semiconductor die;
a second semiconductor die disposed over the first semiconductor die;
a first bonding layer disposed over the second semiconductor die;
a second bonding layer disposed over the first bonding layer;
a high-k layer disposed over the first bonding layer, wherein a first portion of the first bonding layer is surrounded by the high-k layer in a top view; and
a substrate disposed over the high-k layer.

8. The die structure as claimed in claim 7, wherein a portion of the second semiconductor die is surrounded by the high-k layer in the top view.

9. The die structure as claimed in claim 8, wherein a width of the first portion is greater than a width of the second semiconductor die.

10. The die structure as claimed in claim 7, wherein the high-k layer is surrounded by a second portion of the first bonding layer in the top view.

11. The die structure as claimed in claim 7, wherein the first portion and the high-k layer are arranged in a direction parallel to the bottom surface of the substrate.

12. The die structure as claimed in claim 7, wherein the high-k layer is disposed between the first bonding layer and the second bonding layer.

13. The die structure as claimed in claim 7, wherein a first bonding structure is formed in the high-k layer, and a second bonding structure is formed in the second bonding layer that is bonded to the first bonding structure.

14. The die structure as claimed in claim 7, wherein a bonding structure is formed in the first bonding layer and surrounded by the high-k layer in the top view.

15. A method for forming a semiconductor package structure, comprising:
disposing a second semiconductor die over a first semiconductor die;
attaching a substrate to the second semiconductor die using a bonding structure;
heating the bonding structure to a first temperature to form a die structure, wherein the substrate has a first curvature at the first temperature;
placing the die structure over an interposer substrate at a second temperature, wherein the second temperature is lower than the first temperature, the substrate has a second curvature at the second temperature, and the second curvature is greater than the first curvature; and
bonding the die structure to the interposer substrate at a third temperature, wherein the third temperature is higher than the second temperature.

16. The method as claimed in claim 15, wherein the first temperature is between 100° C. and 400° C.

17. The method as claimed in claim 15, wherein forming the bonding structure comprises:
forming a first bonding layer on the second semiconductor die;
forming a high-k layer on the substrate;
forming a second bonding layer on the high-k layer; and
bonding the first bonding layer to the second bonding layer.

18. The method as claimed in claim 17, wherein forming the bonding structure further comprises:
partially removing the high-k layer to form an opening partially exposing the substrate; and
forming the second bonding layer in the opening.

19. The method as claimed in claim 17, further comprising:
partially removing the substrate to form first openings;
forming first bonding features in the first openings;
partially removing the high-k layer to form second openings;
forming second bonding features in the second openings; and
bonding the first bonding features to the second bonding features.

20. The method as claimed in claim 19, further comprising:
partially removing the second bonding layer to form third openings;
forming third bonding features in the third openings; and
bonding the first bonding features to the third bonding features.
